(19) United States
(12) Patent Application Publication
(10) Pub. No.: US 2025/0162735 A1
(43) Pub. Date: May 22, 2025

(54) SYSTEMS, METHODS, AND STORAGE MEDIA FOR CONTROLLING AND SIMULATING SPACECRAFT MANEUVERS

(71) Applicant: True Anomaly Inc., Centennial, CO (US)

(72) Inventors: Benjamin Marx, Venice, CA (US); Daniel Brunski, Colorado Springs, CO (US); Matthew Schmidt, Colorado Springs, CO (US); Shane Dirks, Colorado Springs, CO (US); Noel Kawano, Los Angeles, CA (US)

(73) Assignee: True Anomaly Inc., Centennial, CO (US)

(21) Appl. No.: 18/745,890

(22) Filed: Jun. 17, 2024

Related U.S. Application Data
(60) Provisional application No. 63/509,001, filed on Jun. 19, 2023.

(51) Int. Cl. B64G 3/00; B64G 1/24; G05B 17/02; G08G 5/26

(52) U.S. Cl. CPC B64G 3/00; B64G 1/244; G05B 17/02; G08G 5/26

(57) ABSTRACT

The present disclosure relates to systems, methods, and storage media for controlling and simulating spacecraft maneuvers, where the method comprises requesting, using a pilot vehicle interface, a view of the on-orbit operations, wherein the view comprises at least one object; receiving, from a simulation engine executing on a virtual machine, scenario data describing a status of the on-orbit operations; receiving object information about how the at least one object interacts with the on-orbit operations; integrating the scenario data with the object information to obtain the on-orbit operations; and providing, via the pilot vehicle interface, the view of the on-orbit operations.

### CROSS-REFERENCE TO RELATED APPLICATIONS

The present Application for Patent claims priority to U.S. Provisional Application No. 63/509,001, entitled “Systems, Methods, and Storage Media for Controlling and Simulating Spacecraft Maneuvers,” filed Jun. 19, 2023, assigned to the assignee hereof, the contents of which are incorporated herein by reference in their entirety and for all proper purposes.

### FIELD OF THE INVENTION

Embodiments of the present disclosure relate generally to systems and methods for spacecraft mission technologies and specifically to systems and methods to facilitate space object control and simulation.

### BACKGROUND OF THE INVENTION

Mission technologies are essential to monitor and control space objects. Improved mission technologies, as well as improved training capabilities for operators of the technologies, will allow for better monitoring and control of space objects.

### SUMMARY OF THE INVENTION

A mission control center (sometimes referred to as a flight control center or operations center) is a facility that manages space flights using systems adapted for controlling spacecraft, referred to here as “mission technologies”. Mission technologies may also include systems for simulating spacecraft control. Commercial entities may be involved in mission technologies; for example, they may provide training, monitoring, planning, and other operations related to space flights. Spacecraft security and spacecraft sustainability are important aspects of mission technologies for protecting national and international interests and the implementation of systems and methods that can provide improved capabilities for on-orbit decision making are needed to help support these aspects.

Systems and methods described herein may provide a common platform and interface for space mission operations, training, and simulation. They may feature a high-fidelity modeling and simulation backend tailored for Rendezvous and Proximity Operations (RPO) (including mission planning, and analysis, trade studies) but may be extensible for general purpose astrodynamics simulation. The systems and methods may provide a graphical front-end for input and visualization, including inertial frames, relative frame orthographic projections, waypoint trajectory planning, and information displays. Application Programming Interfaces (APIs) may be available for batch-scripting astrodynamics analysis. The systems and methods described herein may be cloud-based, enabling improved access to “Simulation-as-a-Service”: a high-performance computer architecture supporting massively parallel Monte-Carlo-type analyses and satellite operations from anywhere. This environment may advantageously provide analyses and planning tools for both space defense and commercial Orbital Servicing, Assembly, and Manufacturing (OSAM) applications.

In some aspects, the techniques described herein relate to a method for viewing on-orbit operations, the method including: requesting, using a pilot vehicle interface, a view of the on-orbit operations, wherein the view includes at least one object; receiving, from a simulation engine executing on a virtual machine, scenario data describing a status of the on-orbit operations; receiving object information about how the at least one object interacts with the on-orbit operations; integrating the scenario data with the object information to obtain the on-orbit operations; and providing, via the pilot vehicle interface, the view of the on-orbit operations.

In some aspects, the techniques described herein relate to a method, wherein the at least one object includes at least one of a ground station and at least one of a satellite.

In some aspects, the techniques described herein relate to a method, wherein the scenario data includes launch information, and wherein the object information includes a calculation of orbital data that is based on the launch information.

In some aspects, the techniques described herein relate to a method, wherein the at least one object is not on-orbit, and wherein the view of the on-orbit operations is a simulation of at least two scenarios of the at least one object being on-orbit.

In some aspects, the techniques described herein relate to a method, wherein after the view of the simulation, the at least one object is on-orbit and a second view is provided that displays on-orbit information for the at least one object after it is on-orbit.

In some aspects, the techniques described herein relate to a method, wherein the view of the on-orbit operations includes a first simulation that models a first on-orbit maneuver of the at least one object, and further including: providing a second view of the on-orbit operations that includes a first simulation that models a first on-orbit maneuver of the at least one object; requesting the view of the on-orbit operations a second time; providing the view, wherein the view reverts back in time to remove the first simulation; requesting a third view of the on-orbit operations that includes a second simulation that models a second on-orbit maneuver of the at least one object; and providing the third view of the on-orbit operations that includes the second simulation that models the second on-orbit maneuver of the at least one object.

In some aspects, the techniques described herein relate to a method, wherein the view of the on-orbit operations is a view of simulated operations, and further including requesting a second view of the on-orbit operations, wherein the second view includes real-time operations of the at least one object; and providing the second view of the real-time operations.

In some aspects, the techniques described herein relate to a method, further including requesting an on-orbit maneuver of the at least one object; and sending, via the scenario manager, a command to execute the on-orbit maneuver to the at least one object.

In some aspects, the techniques described herein relate to a method, further including receiving, from an AI agent, an action to maneuver the at least one object.

In some aspects, the techniques described herein relate to a method, wherein the action is provided as a simulation in the view by the pilot vehicle interface.

In some aspects, the techniques described herein relate to a method, wherein the at least one object is on-orbit in real-life, and further including receiving a confirmation of the action and sending a command to execute the action in real-life to the at least one object.

In some aspects, the techniques described herein relate to a method, wherein the command is executed faster than in real-time.

In some aspects, the techniques described herein relate to a method, further including sending, by the scenario manager, a command to the at least one object that is on-orbit that causes the at least one object to execute a maneuver.

In some aspects, the techniques described herein relate to a method, further including receiving, by the scenario manager, telemetry data from the at least one object, wherein the telemetry data is based on the command.

In some aspects, the techniques described herein relate to a system for viewing on-orbit operations, the system including: a simulation engine executing on a virtual machine, the simulation engine providing scenario data describing a status of the on-orbit operations; and a pilot vehicle interface requesting a view of the on-orbit operations, receiving the scenario data from the simulation engine, receiving object information about how an at least one object interacts with the on-orbit operations, integrating the scenario data with the object information to obtain the on-orbit operations; and providing the view of the on-orbit operations.

In some aspects, the techniques described herein relate to a system, wherein the simulation engine executes in at least five modes, the modes including: command and control, space battle management, battlespace, tactical decision aids, and digital space range.

In some aspects, the techniques described herein relate to a system, wherein the at least one object is viewed as a launch vehicle analysis in each of the five modes.

In some aspects, the techniques described herein relate to a system, wherein a state estimation library is used in the battlespace mode to provide a white cell.

In some aspects, the techniques described herein relate to a system, wherein the pilot vehicle interface executes on the virtual machine.

In some aspects, the techniques described herein relate to a system, wherein the system relies on a single clock.

These and other features, and characteristics of the present technology, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the disclosure. As used in the specification and in the claims, the singular form of ‘a’, ‘an’, and ‘the’ include plural referents unless the context clearly dictates otherwise.

### BRIEF DESCRIPTION OF THE DRAWINGS

FIG. 1 is an illustrative architecture diagram for a mission control and simulation system in accordance with at least some embodiments of the present disclosure.

FIG. 2 is a view of an illustrative launch window analysis in accordance with at least some embodiments of the present disclosure.

FIG. 3 is a view of an illustrative launch window analysis in accordance with at least some embodiments of the present disclosure.

FIG. 4 is a view of an illustrative sensor scheduler and visibility windows in accordance with at least some embodiments of the present disclosure.

FIG. 5 is a view of an illustrative residuals analysis display in accordance with at least some embodiments of the present disclosure.

FIG. 6 is a view of an illustrative covariance analysis display in accordance with at least some embodiments of the present disclosure.

FIG. 7 is a view of an illustrative Point of Close Approach display in accordance with at least some embodiments of the present disclosure.

FIG. 8 is a view of an illustrative transfer analysis display in accordance with at least some embodiments of the present disclosure.

FIG. 9 is a view of an illustrative transfer analysis display in accordance with at least some embodiments of the present disclosure.

FIG. 10 is a view of an illustrative avoidance analysis display in accordance with at least some embodiments of the present disclosure.

FIG. 11 is a view of an illustrative latitude and longitude view in accordance with at least some embodiments of the present disclosure.

FIG. 12 is a view of an illustrative relative frame view in accordance with at least some embodiments of the present disclosure.

FIG. 13 shows a view of an illustrative development of a maneuver strategy in accordance with at least some embodiments of the present disclosure.

FIG. 14 shows a view of an illustrative relative frame view in accordance with at least some embodiments of the present disclosure.

FIG. 15 shows a view of an illustrative development of a maneuver strategy in accordance with at least some embodiments of the present disclosure.

FIG. 16 is an illustrative block diagram of an agent engine in accordance with at least some embodiments of the present disclosure.

FIG. 17 is an illustrative method in accordance with at least some embodiments of the present disclosure.

### DETAILED DESCRIPTION

### Definitions and Terminology used in the disclosure

As used herein, a communication may also be referred to as a “message,” and a “communication session” and may include one or multiple electronic records, text, rich media, or data structures that are transmitted from one communication device to another communication device via a communication network. A communication may be transmitted via one or more data packets and the formatting of such data packets may depend upon the messaging protocol used for transmitting the electronic records over the communication network.

As used herein, a data model may correspond to a data set that is useable in an artificial neural network and that has been trained by one or more data sets that describe conversations or message exchanges between two or more entities. The data model may be stored as a model data file or any other data structure that is useable within a neural network or an Artificial Intelligence (AI) system. The term “Artificial Intelligence” as used herein generally refers to machine intelligence that includes a computer model or algorithm that may be used to provide actionable insight, make a prediction, and/or control actuators. The AI may be a machine learning algorithm. The machine learning algorithm may be a trained machine learning algorithm, e.g., a machine learning algorithm trained from data. Such a trained machine learning algorithm may be trained using supervised, semi-supervised, or unsupervised learning processes. Examples of machine learning algorithms include neural networks, support vector machines and reinforcement learning algorithms.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

The term “automatic” and variations thereof, as used herein, refers to any process or operation done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

The term “computer-readable medium” as used herein is used interchangeably with the terms “computer-readable media” and “storage media” and refers to any tangible storage and/or transmission medium that participate in providing instructions to a processor for execution. Such a medium may take many forms, including but not limited to, non-volatile media, volatile media, and transmission media. Non-volatile media may be referred to herein as storage media and includes, for example, NVRAM, or magnetic or optical disks. Volatile media may be referred to herein as storage media and includes dynamic memory, such as main memory. Common forms of computer-readable media include, for example, a floppy disk, a flexible disk, hard disk, magnetic tape, or any other magnetic medium, magneto-optical medium, a CD-ROM, any other optical medium, punch cards, paper tape, any other physical medium with patterns of holes, a RAM, a PROM, and EPROM, a FLASH-EPROM, a solid state medium like a memory card, any other memory chip or cartridge, a carrier wave as described hereinafter, or any other medium from which a computer can read. A digital file attachment to e-mail or other self-contained information archive or set of archives is considered a distribution medium equivalent to a tangible storage medium. When the computer-readable media is configured as a database, it is to be understood that the database may be any type of database, such as relational, hierarchical, object-oriented, and/or the like. Accordingly, the disclosure is considered to include a tangible storage medium or distribution medium and prior art-recognized equivalents and successor media, in which the software implementations of the present disclosure are stored.

A “computer readable signal” medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable medium may be transmitted using any appropriate medium, including but not limited to wireless, wireline, optical fiber cable, RF, etc., or any suitable combination of the foregoing.

The terms “determine,” “calculate,” and “compute,” and variations thereof, as used herein, are used interchangeably and include any type of methodology, process, mathematical operation or technique.

It shall be understood that the term “means” as used herein shall be given its broadest possible interpretation in accordance with 35 U.S.C., Section 112, Paragraph 6. Accordingly, a claim incorporating the term “means” shall cover all structures, materials, or acts set forth herein, and all of the equivalents thereof. Further, the structures, materials or acts and the equivalents thereof shall include all those described in the summary of the disclosure, brief description of the drawings, detailed description, abstract, and claims themselves.

Aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Any combination of one or more computer readable medium(s) may be utilized. The computer readable medium may be a computer readable signal medium or a computer readable storage medium.

In yet another embodiment, the systems and methods of this disclosure can be implemented in conjunction with a special purpose computer, a programmed microprocessor or microcontroller and peripheral integrated circuit element(s), an ASIC or other integrated circuit, a digital signal processor, a hard-wired electronic or logic circuit such as discrete element circuit, a programmable logic device or gate array such as PLD, PLA, FPGA, PAL, special purpose computer, any comparable means, or the like. In general, any device(s) or means capable of implementing the methodology illustrated herein can be used to implement the various aspects of this disclosure. Illustrative hardware that can be used for the disclosed embodiments, configurations, and aspects includes computers, handheld devices, telephones (e.g., cellular, Internet enabled, digital, analog, hybrids, and others), and other hardware known in the art. Some of these devices include processors (e.g., a single or multiple microprocessors), memory, nonvolatile storage, input devices, and output devices. Furthermore, alternative software implementations including, but not limited to, distributed processing or component/object distributed processing, parallel processing, or virtual machine processing can also be constructed to implement the methods described herein.

Examples of the processors as described herein may include, but are not limited to, at least one of Qualcomm® Snapdragon® 800 and 801, Qualcomm® Snapdragon® 610 and 615 with 4G LTE Integration and 64-bit computing, Apple® A7 processor with 64-bit architecture, Apple® M7 motion coprocessors, Samsung® Exynos® series, the Intel® Core™ family of processors, the Intel® Xeon® family of processors, the Intel® Atom™ family of processors, the Intel Itanium® family of processors, Intel® Core® i5-4670K and i7-4770K 22 nm Haswell, Intel® Core® i5-3570K 22 nm Ivy Bridge, the AMD® FX™ family of processors, AMD® FX-4300, FX-6300, and FX-8350 32 nm Vishera, AMD® Kaveri processors, Texas Instruments® Jacinto C6000™ automotive infotainment processors, Texas Instruments® OMAP™ automotive-grade mobile processors, ARM® Cortex™-M processors, ARM® Cortex-A and ARM926EJ-S™ processors, other industry-equivalent processors, and may perform computational functions using any known or future-developed standard, instruction set, libraries, and/or architecture.

In yet another embodiment, the disclosed methods may be readily implemented in conjunction with software using object or object-oriented software development environments that provide portable source code that can be used on a variety of computer or workstation platforms. Alternatively, the disclosed system may be implemented partially or fully in hardware using standard logic circuits or VLSI design. Whether software or hardware is used to implement the systems in accordance with this disclosure is dependent on the speed and/or efficiency requirements of the system, the particular function, and the particular software or hardware systems or microprocessor or microcomputer systems being utilized.

In yet another embodiment, the disclosed methods may be partially implemented in software that can be stored on a storage medium, executed on programmed general-purpose computer with the cooperation of a controller and memory, a special purpose computer, a microprocessor, or the like. In these instances, the systems and methods of this disclosure can be implemented as program embedded on personal computer such as an applet, JAVA® or CGI script, as a resource residing on a server or computer workstation, as a routine embedded in a dedicated measurement system, system component, or the like. The system can also be implemented by physically incorporating the system and/or method into a software and/or hardware system.

Methods described or claimed herein can be performed with traditional executable instruction sets that are finite and operate on a fixed set of inputs to provide one or more defined outputs. Alternatively, or additionally, methods described or claimed herein can be performed using artificial intelligence (AI), machine learning (ML), neural networks, or the like. In other words, a system is contemplated to include finite instruction sets and/or artificial intelligence-based models/neural networks to perform some or all of the steps described herein.

The term “agent” as used herein includes the terms user, operator, player, AI agent, and human agent, among others. The term “agent” may be an AI agent or a human agent and also includes a human-agent team (e.g., a system composed of one or more interacting humans and AI systems).

The term “object” as used herein may refer to any space objects, any ground objects, including vehicles, targets, ground stations, assets (e.g., high value assets (HVAs), Jackals, satellites, etc.), weapons, and service providers, among others. The term “object” may refer to various types of infrastructure and equipment (e.g., civilian, private, public, commercial, and/or military) including objects at fixed locations (e.g., launch sites that are not mobile) and objects at mobile locations (such as mobile ground launch locations and vehicles (manned and unmanned)). Further examples of objects include landers, launchers, capsules, and shuttles. Objects may be friendly objects (e.g., sometimes called a “blue” object that is not considered a threat) or a threat object (e.g., sometimes called a “red” object that is considered a threat).

As used herein, the term “time window” is used interchangeably herein with the terms timing of windows, timing windows, windows of time, and windows of timeframes. The term “time window” may be described by a type of window that is associated with an objective of the timing (e.g., a launch window, a visibility window, etc.).

### Embodiments of the Disclosure

In the following description, for the purposes of explanation, numerous specific details are set forth in order to provide a thorough understanding of various embodiments disclosed herein. It will be apparent, however, to one skilled in the art that various embodiments of the present disclosure may be practiced without some of these specific details. The ensuing description provides illustrative embodiments only and is not intended to limit the scope or applicability of the disclosure. Furthermore, to avoid unnecessarily obscuring the present disclosure, the preceding description omits a number of known structures and devices. This omission is not to be construed as a limitation of the scope of the claims. Rather, the ensuing description of the illustrative embodiments will provide those skilled in the art with an enabling description for implementing an illustrative embodiment. It should however be appreciated that the present disclosure may be practiced in a variety of ways beyond the specific detail set forth herein.

While the illustrative aspects, embodiments, and/or configurations illustrated herein show the various components of the system collocated, certain components of the system can be located remotely, at distant portions of a distributed network, such as a Local Area Network (LAN) and/or the Internet, or within a dedicated system. Thus, it should be appreciated, that the components of the system can be combined in to one or more devices or collocated on a particular node of a distributed network, such as an analog and/or digital telecommunications network, a packet-switched network, or a circuit-switched network. It will be appreciated from the following description, and for reasons of computational efficiency, that the components of the system can be arranged at any location within a distributed network of components without affecting the operation of the system.

Various additional details of embodiments of the present disclosure will be described below with reference to the figures. While the flowcharts will be discussed and illustrated in relation to a particular sequence of events, it should be appreciated that changes, additions, and omissions to this sequence can occur without materially affecting the operation of the disclosed embodiments, configuration, and aspects.

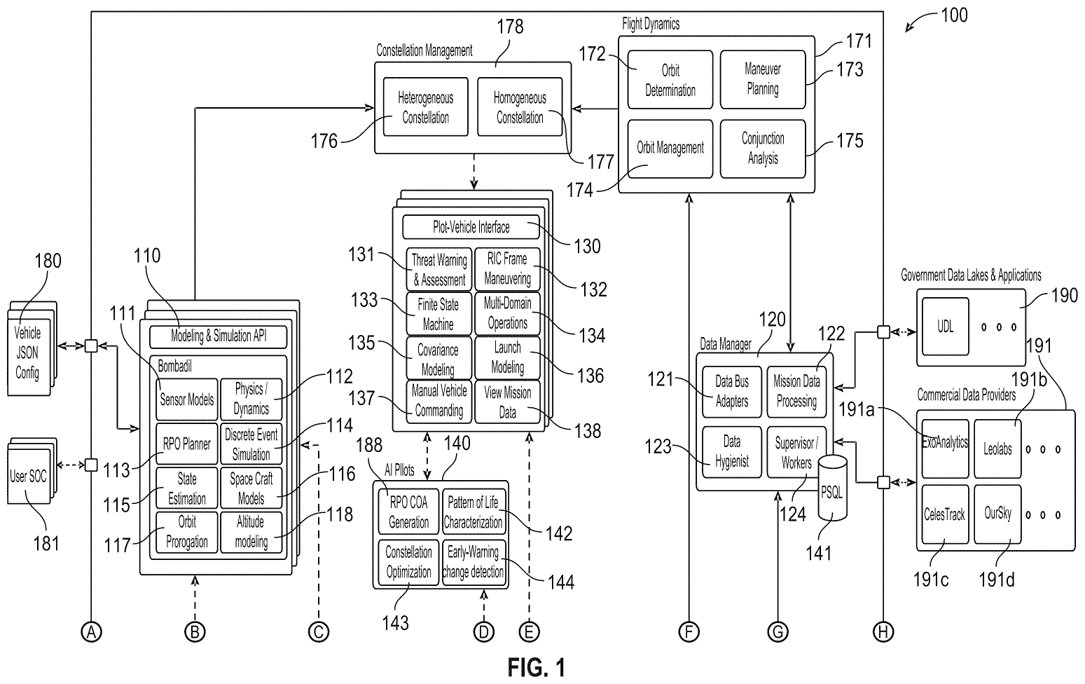

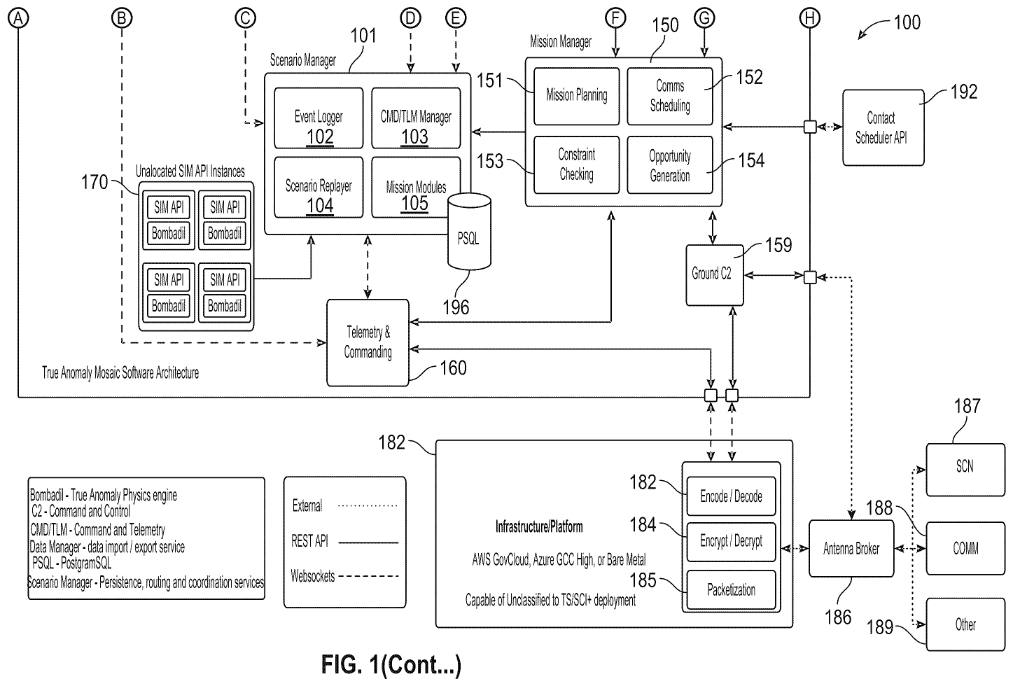

Referring initially to FIG. 1, FIG. 1 shows an illustrative system architecture 100 (also referred to as system 100) in accordance with at least some embodiments of the present disclosure. In some aspects, FIG. 1 shows an illustrative system for mission control (referred to herein as the “Mosaic” system or “Mosaic”) with various components within the system including, for example, a scenario manager 101 (interfacing with a PostgreSQL (“PSQL”) database 196 and including an event logger 102, a command and telemetry (“CMD/TLM”) manager 103, a scenario replayer 104, and mission modules 105), a modeling and simulation application programming interface (“API”) 110 sensor models API 111, physics/dynamics API 112, RPO planner API 113, discrete event simulation API 114, state estimation API 115, spacecraft models API 116, orbit propagation API 117, and altitude modeling API 118), a data manager service 120 (interfacing with a PSQL database 198 and including data bus adaptors 121, mission data processing 122, data hygienist 123, and supervisor/workers 124), and a graphical user interface (“GUI”) (e.g., pilot vehicle interface 130 that includes threat warning and assessment 131, Radial, In-track, and Cross-track (RIC) frame maneuvering 132, finite state machine 133, multi-domain operations 134, covariance modeling 135, launch modeling 136, manual vehicle commanding 137, and view mission data 138).

In various aspects, data bus adaptors 121 refers to an ability to ingest or export data by interfacing with a provider. The bus itself may be agnostic and can communicate over whatever protocol and transport layer is required (e.g., HTTP and JSON). Mission data processing 122 may refer to telemetry that is downlinked and used for mission planning. For example, telemetry data may be GPS data that shows the location of a satellite, and this data can have various uses, e.g., orbit determination. Images that have been downlinked from the satellite may also be stored. Data hygienist 123 may refer to standardization and sanitization of data that do not follow a consistent schema, e.g., data that is received from different providers. Supervisors/workers 124 may refer to having a worker for each data provider, where the worker fetches and enters the data into the database at a per-provider configured interval. A supervisor manages all of the workers and if a worker fails, the supervisor can restart the worker without human intervention.

In various embodiments, the modeling and simulation API 110 is embedded into a SIM API service (e.g., unallocated SIM API instances 170). A SIM API instance may be considered a virtual machine instance. Embodiments disclosed herein may run on multiple virtual machines. The GUI 130 may communicate with AI pilots 140 which may include an RPO COA (“course-of-action”) generation 141, pattern of life characterization 142, constellation optimization 143, and early-warning change detection 144. The AI pilots 140 and GUI 130 may communicate with the scenario manager 101. Data from the unallocated SIM API instances 170 and a mission manager 150 (which includes, for example, mission planning 151, comms scheduling 152, constraint checking 153, and opportunity generation 154, among others) may be input to the scenario manager 101. The mission manager 150 may be a module in the physics engine and may be exposed through a C API that the Elixir application, SIM API, then exposes through a REST, gRPC (e.g., a framework for Remote Procedure Calls), or WebSocket API. Mission planning 151 may include comms scheduling 152, constraint checking 153, and opportunity generation 154, among others. These modules may be used to validate a plan when planning a mission. For example, if any of the modules throw a warning or returns a violation, the mission plan may be aborted.

Comms scheduling 152 may enable an operator to schedule comms and ensure that the lighting constraints are correct and that the satellite is pointed in a sufficient, improved, or an optimal direction in order to have a successful contact (e.g., a contact that is desired or defined by a mission plan). Constraint checking 153 may include checking whether a mission plan violates any constraint, where constraints can include lighting, license constraints (e.g., Federal Communications Commission (FCC), National Oceanic and Atmospheric Administration (NOAA), etc.), and distance constraints, among others. Opportunity generation 154 refers to showing when a sufficient, improved, or optimal time is in order to take an action regarding a target (e.g., engage a target, image a target, etc.).

A telemetry and commanding service 160 may communicate with scenario manager 101, modeling and simulation API 110, mission manager 150, and other infrastructure/platform services 182. The Mosaic system may further include constellation management services 178 (which includes, for example, heterogeneous constellation 176 and homogenous constellation 177, each of which provide information about elements of the configurations of their respective constellations) that receives input from modeling and simulation API 110 and also receives input from flight dynamics 171 (which includes, for example, orbit determination 172, maneuver planning 173, orbit management 174, and conjunction analysis 175). Flight dynamics may communicate with mission manager 150 and data manager 120. Mission manager 150 may communicate with ground command and control (“C2”) 159. The data manager service 120 can import and export data, and one or more identification and authorization components may provide identification and authorization systems and methods for the Mosaic system. For example, elements may communicate over an exposed C API or over a message queue such as ZeroMQ. As a further example, scenario manager 101 elements may communicate over gRPC or directly through a python API (which may, in some instances, be used instead of a web interface). In some aspects, mission engineering may work with python API and a space operations team, and external customers may use scenario manager 101 through gRPC, REST, and web socket APIs that may be exposed as web interface APIs. In some aspects, the systems and methods disclosed herein primarily include four services of the scenario manager 101, the modeling and simulation (“M&S”) API 110, the data manager service 120, and the PVI 130.

In some aspects, APIs may be exposed to C and Python where necessary, and code may be written in C++ for advantageous speed. Various embodiments of system 100 enables universal and plug-and-play mission control software (“MCS”) APIs. In such embodiments, one or more of the components of system 100 comprise services that have interchangeable parts that can be used with different vendor software or custom software components. In one such example, the system may enable different flight software or custom command and telemetry databases for distinct spacecraft. In some embodiments, custom and extensible data providers can be added through, for example, a provider behavior. Advantageously, systems and methods disclosed herein may be agnostic to encryption schemes, and the system may be scalable across various RPO missions. Additionally, the system and methods disclosed herein may support many (e.g., hundreds) of concurrent satellites and each satellite's command and control may be isolated through specific channels providing fault tolerance and isolated failure.

In some aspects, the Mosaic system (and/or components thereof) may communicate with other elements. For example, the modeling and simulation API 110 may communicate with vehicle JSON config 180. Communications with the JSON configs may comprise internal communications. In various aspects, an internal defined JSON schema may be used. In further aspects, an actual JSON can be imported by an external user conforming the JSON schema being used internally. For example, an internal JSON schema may be used by internal purposes and also by external parties in order to create a satellite or a ground station via the JSON schema. These communications, and others, may be stored in Git system repository. Alternatively, internal communications such as, but not limited to, the JSON config communications, may be included in a service communication such as, but not limited to, a REST API communication. Config files and communications, such as, but not limited to, the modeling and simulation (M&S) API 110, may be received from external sources (e.g., for specific missions). It is also contemplated that such communication may be loaded as a JSON file. A user Space Operations Center (SOC) 181 may also communicate with the Mosaic system. The user SOC may be internal or external to the system. Ground C2 159 may communicate with an antenna broker 186 as well as with infrastructure/platform 182 which may include encode/decode 183, encrypt/decrypt 184, and packetization 185 modules, respectively. Antenna broker 186 may communicate with Satellite Control Network (SCN) 187, Commercial (COMM) 188, and other services 189. One SCN may comprise the Space Force's network of antennas for commanding satellites. Commercial may comprise commercial ground control equipment and/or satellites. The Mosaic system 100, via data manager 120, may communicate with government data lakes and applications 190, which may include a Unified Data Library (“UDL”), such as, but not limited to, https://unifieddatalibrary.com, commercial data providers 191 such as ExoAnalytics (https://unifieddatalibrary.com) 191a, LeoLabs (https://leolabs.space/) 191b, CelesTrack (https://celestrak.org/) 191c and OurSky (oursky.ai) 191d, to name a few, and contact scheduler API 192. Libraries may include, and are not limited to a Numerical Algorithms Library (e.g., containing general numerical algorithms, similar to what would be found in Python's script library), an Astrodynamics Library (e.g., a general astrodynamics library for handling time, high-fidelity propagation, computing maneuvers, etc.), a Discrete Event Simulation (DES) (e.g., custom implementation of a discrete event simulation), an Attitude Dynamics Library (e.g., contains logic for propagating the attitude of a satellite forward in time), a Filtering Library (e.g., a general filtering library, built to generate measurements from instruments and process them in filters), a RPO Mission Planning Library (e.g., a library built to allow RPO missions to be scheduled on the DES through Finite State Machines (FSM), allowing for complex missions to be build, where it may also define metrics for triggering events and logging information), and/or, a State Estimation Library (e.g., a library built to allow state estimation and relative navigation to be performed within the DES), among others.

Embodiments of the M&S environment described herein include illustrative algorithms and capabilities. In various embodiments, astrodynamics algorithms may be dependent on robust and efficient numerical algorithms. Modeling high fidelity propagation may require numerical integration or ordinary differential equations (ODEs). Embodiments may include computing visibility intervals and range metrics require efficient root solvers. In various aspects, optimizing maneuver plans may require optimization algorithms having improved flexibility and efficiency. In some aspects, the numerical algorithms (e.g., numalg) library is designed to meet these needs, and algorithms are only implemented when they support the astrodynamics related libraries. Various libraries and algorithms may be incorporated with the systems and methods disclosed herein, as described in Appendix A. Appendix A is incorporated fully by reference.

In various embodiments, scenario manager service 101 works with other components of the system to execute various modes. These modes may include (i) spacecraft command and control, which may include the pilot vehicle interface used to operate live spacecraft, plan missions, and receive telemetry, with decision-support from AI, (ii) space battle management, which may include systems and AI necessary to make sense of activity in an identified domain to make spacecraft decisions and control tactical and/or other units, (iii) battlespace, which may comprise a multiplayer wargaming environment for exercises and wargames utilizing realistic asset models and user-specific perspectives across military space missions, (iv) tactical decision aids, which may include systems to automate specific processes and synthesize complex data into actionable information for system users, which may be referred to as space operators, and (v) digital space range, which may comprise digital representations of spacecraft, sensors, and payloads to test orbital activities and validate tactics.

In some aspects, scenario manager service 101 may communicate with the modeling and simulation API 110 to execute a modeling and simulation engine (also referred to as a simulation engine). In some embodiments, the modeling and simulation API 110 may also be referred to as a SIM API and it may use Elixir with a REST API and modeling simulation engine information injected at compile time in order to calculate data sets based on selection of a mode and corresponding input. The data sets may be sent over a REST API, a WebSocket API, or via gRPC to the pilot vehicle interface (PVI) 130. In some embodiments, cloud services may enable the delivery aspects of the system 100 including the modeling and simulation API 110. In some advantageous aspects, because some of most of the functionality (e.g., the physics, persistence, etc.) on the backend, it is possible to leverage the backend in whole or in part for different applications, such as those described herein. For example, a headless API may be used with a PVI having an AstroUX-inspired frontends. The modeling and simulation API 110 may also include various APIs, such as an API for physics and weather modeling data (e.g., via a REST API, WebSocket API, etc.). Thus, various data may be input into the modeling and simulation engine at a compile time. For example, new data sets may be added into the physics engine which would then be added during compilation. It is contemplated that user data may be added after the application has compiled. In some embodiments, the modeling simulation and API 110 may contain any number of different modes that may be executed. One example of a mode is simulation. Another example of a mode is battlespace (e.g., a wargaming scenario). Yet another mode may be on-orbit operations. In some embodiments, battle management may be a simulated or real scenario whereas on-orbit operations may be with actual satellites that could be engaged in one or more operations. Further modes may include tactically responsive space and digital range or other aspects described above related to the scenario manager service 101.

In some embodiments, the system and methods disclosed herein may reuse data to execute scenarios (where the term “scenarios” includes exercises) and repeat one or more portions of a scenario. For example, sometimes the system may repeat aspects of some or all of a specific scenario. The scenario manager 101 may be responsible for persisting data that is used in some scenarios. As a further example, in a space battle management scenario, an operator may create objects within the scenario (e.g., satellites) and configure other information, as well as perform any number of maneuvers (e.g., launch one or more objects such as satellites). Any or all of this data may be persisted in the scenario manager 101. Each scenario, regardless of the type, may have a SIM API that is configured and/or executed and attached to the scenario, or the scenario manager 101, for the life of that scenario. In some systems, all of the data in the SIM API is in memory only (e.g., one or more databases). However, because data may be persisted in the scenario manager 101, the data may persist through different instances or different scenarios (e.g., the data may persist even if an API crashes, if it's disconnected, or if it reboots). This advantageously allows the Mosaic system to execute actions such as replay, as well as replay together with changing to a different maneuver during the replay (e.g., such as implementing counterfactuals at some point in time).

In some aspects, the systems and methods disclosed herein advantageously allow operators to train on the same system that they could also execute operations (e.g., run missions, fly, etc.) on. For example, the same code path(s) and/or exercise(s) may be used by an operator in a training scenario as are used in an operations scenario. This may be possible by using a SIM API to store created scenarios so that planning a mission can occur in the same system that the training occurred on. In one such example, the scenario manager 101 may store the data and subsequent planning or loading of the stored scenario may occur on different SIM API instances, which may be assigned randomly at scenario start, load, or reattachment.

In various aspects, a difference between planning and training is the use of a command and control (C2) component. Various software may be used for command and control, such as software by MAX Ground Data System (GDS) by Rocket Lab ASI, Ball Aerospace Open C3, or other custom developed C2 Software. Advantageously, the ability to use different software systems allows the system to be able to have modular components. For example, in various embodiments, it is possible to swap out one encryption scheme for another, and/or to add on new backends or versions of backends (e.g., simulated flight software, hardware, etc.). Further, additional data sources and/or providers can be added with advantageous ease, so that it is possible to ingest and/or export additional data. Further, it is advantageously possible to add in controls for satellites that are external to (e.g., not part of) the system.

In further embodiments, other components may advantageously be modular (such as the use of different command and telemetry databases). For example, for each mission, each spacecraft may have unique command and telemetry data. In some aspects, if a third-party company were using MAX flight software, the presently disclosed system advantageously allows command and telemetry database to be imported for use within the presently disclosed system. Furthermore, the modularity provides benefits of reduced friction for implementation and changing of various components, and ease of ability to use this system to control various satellites even if they are new to this system. Further advantages include that, when the operator makes plans to maneuver, the operator may confirm the maneuver and then the maneuver may be executed faster than in real-time. For example, the system may send the commands out through scenario manager 101 into the command-and-control component (e.g. Ground C2 159), which would manage the commands as necessary. In some aspects, the simulation engine can run much faster than real-time because it contains a model of the universe with objects (e.g., celestial bodies, satellites, ground stations, rockets, etc.). A software in the loop (SIL) application may run MAX Flight Software that is faster than real-time called FTRT SIL. In various aspects, FTRT SIL may be an improved representation, or the most faithful representation, of the flight software. Operators may run a maneuver or mission plan through FTRT SIL before executing the plan with the real satellites. The command(s) may communicate directly to the spacecraft (e.g., if it is a basic command) or the command may be a sequence of commands. In some embodiments, the command may be a sequence of commands that use a scripting language such as FlightJAS and are communicated to the ground stations (e.g., the service provider). Still further, it is contemplated that the commands may be sent out over WebSockets and may then be communicated to a satellite. Furthermore, the commands may be communicated to another system and translated into the relevant protocol and then communicated to the satellite. The satellite may then decode and decrypt the commands, which are then read by the satellite and telemetry data may be communicated.

Telemetry data may be the information about an object (e.g., a satellite), including any and all information. Telemetry data describes the state of the object. The information may include information provided by the satellite about its date and time, position, velocity, and any or all of the subsystems (e.g., all of the subsystems that compose the satellite). The ability to communicate telemetry data is advantageous in various aspects because external imagery may not show as much information about the object, such as whether solar arrays have deployed, if it is sun-pointing, and whether its tumbling, among other information.

As described herein, systems and methods may incorporate one or more ground stations. Information about ground stations may be obtained using systems such as one or more of Azure orbital and/or ViaSat, among others, and any of these could be swapped out advantageously for modularity. Aspects of the systems and methods disclosed herein have advantageous modularity by using connections at the edge of the system (e.g., at the edge of the Mosaic system, such as vehicle JSON config 180, user SOC 181, Government Data Lakes and Applications 190, Commercial Data Providers 191, Contact Scheduler API 192, Antenna Broker 186, and other infrastructure/platform services 182). For example, data communications for components such as infrastructure and/or command and control and/or ground stations, among other components, may be changed with more ease for the systems and methods disclosed herein (e.g., using an API). This may advantageously provide additional redundancy and fault tolerance to the systems and methods.

Turning to the data manager service 120, data may be imported from any number of commercial and government sources. In various embodiments, components herein may use languages that make them easier to interface with other components. For example, scenario managers (e.g., scenario manager 101) and an API data manager may use Elixir. In various embodiments, a construct called the behavior in Elixir may provide an interface that is easier and faster to interface with other languages. Advantageously this may allow a faster and easier ability to ingest data from any number of providers. One example of this functionality is the use of space track so that an operator can import objects in the sky when using the systems and methods described herein to execute various tactics, development, training, and/or Wargaming, among other functionality to ingest data. Further advantages include that these systems and methods (including the communications functionality described herein) improve integration with any classified environment, e.g., by making it faster and easier, such as by being able to add a new provider as opposed to re-architecting part of the systems. Still further, regarding other components such as bus adapters, services such as GMSEC (Goddard Mission Services Evolution Center), UCI (Universal Command and Control Interface), etc. may advantageously be incorporated.

In various embodiments, the PVI may include access to live system status and control of satellites, modeling and simulation for future architecture studies, gaming platform for multiplayer orbital warfare training, and assist maneuver planning with AI. AI pilots, in various embodiments, may be developed using deep reinforcement learning (RL) agents. The AI agents may be trained on any number of scenarios (e.g., runs, which may number in the hundreds of millions), and the scenarios may be exported into a data set, such as a set of matrices.

AI agents may be developed using an in-house developed RL framework. They may be built to be lightweight with improved modularity, speed, and have improved ease to debug. Systems and methods disclosed herein may train AI agents as they play many (e.g., thousands or millions) of individual RPO engagements and the AI agents may be trained in a set of OpenAI Gym compliant environments, which can serve to wrap the simulator in such a way to expose task specific functionality. In some aspects, the agents get integrated into the simulator (PVI backend) and have tasks that include cooperative inspection, and 1v1 (e.g., one player versus one player) OEM (e.g., dogfighting), orbital intercept (ingress) and extract learning weights directly from the network and load them into C++ code. This may advantageously lower overhead because embodiments may not require additional C++ packages to execute. Advantageously, this may allow the AI to function as a tactical decision aid for operators, where the agents autonomously map out waypoint plans that the operator then only needs to verify. Automation may be enabled, at least in part, via Expert Systems using Finite State Machines (FSM). States may specify various semi-autonomous behaviors, where goals are defined parametrically and maneuvers are calculated on the fly, and transitions between states may be controlled by user defined criteria using real-time data. State machines may allow canonical RPO primitive behaviors (e.g., Forced Motion Circumnavigation, linear drift) to be strung together into a complete mission plan, and pre-constructed state machines may enable automated behaviors of both adversaries and allies for training purposes. In some embodiments, each of these behaviors may be context-dependent (e.g., where they are in space and in relation to something else) but they can be run independently or combined to achieve desired effects. In various aspects, the behaviors can also be conditionally triggered; for example, a condition of going x kilometers close to a specified target and then doing a force motion circumnavigation (FMC) or if y amount of delta V is used then do another maneuver. In some advantageous aspects, this ability provides an operator a more open space to conduct an operation especially if the target is non-cooperative, uncooperative, or there is uncertainty about the location of a target, regardless of whether the target is friendly or otherwise.

Advantageously, the exported data may perform variations to the scenario(s) to determine improved actions to take within the scenarios. For example, the matrices may be compiled into a bar model for use with a physics engine to be used in a maneuver which may include various pre-defined maneuver types (such as, but not limited to, wheel or perch) or any algorithmically determined maneuvers, and the deep reinforcement learning agents may also be used in such a manner, with provided or otherwise, applied criteria. Thus, in various embodiments, a target may be performing a maneuver or some action and the systems may determine, based on the conditions, what decision to make (e.g., the agent may determine what decision(s) to make). Using the systems and methods disclosed herein, it is possible to project the choices forward in time to create potential scenarios and determine, for example, how the agent would perform. It is possible to view potential results and select specific scenarios to save and execute. Further advantageous embodiments allow the ability to analyze backward and forward in time in the scenario(s). For example, it is possible to analyze between two or more different maneuvers based on different criteria, e.g., based on what an operator thinks a target may do. This provides advantages with methods and modes such as training, tactics development, gaming, etc., where an operator may better understand what an object does and how different actions and decisions (including the details and effects of taking a discrete number of steps and/or the details and effects of taking each step within the number of steps) affect outcomes of scenarios and maneuvers.

In some examples, the system and methods may take a specified number of steps where, at a predetermined step, each instance of the scenario is going to execute a different decision (e.g., a different maneuver or a same maneuver with different conditions) to determine what the outcome of the decision would be. Advantageously, this provides functionality to see how to see how the different decisions could change the results. Various components of the systems and methods disclosed herein enable this functionality.

As described herein, scenario manager service 101 works with other components of the system to execute various modes (e.g., spacecraft command and control (the pilot vehicle interface used to operate live spacecraft, plan missions, and receive telemetry, with decision-support from AI), space battle management (the systems and AI necessary to make sense of activity in the domain to make decisions and control tactical units), battlespace (which may be referred to as battlespace and is a multiplayer wargaming environment for exercises and wargames utilizing realistic asset models and user-specific perspectives across all of the military space missions), tactical decision aids (systems created to automate specific processes and synthesize complex data into actionable information for space operators), and digital space range (digital representations of spacecraft, sensors, and payloads to test orbital activities and validate tactics)).

These modes may advantageously share backend architecture for simulations including storage media, systems and methods. However, spacecraft command and control controls spacecraft that are in orbit. In some aspects, the architecture is a service-oriented architecture (SOA) where each service has an exposed API that one or more services may communicate with. Roughly each service provides a set of capabilities or functionality that can be combined with other services to achieve one or more desired effects. SIM API is the embedded physical and simulation and it communicates with scenario manager 101. Scenario manager 101 may maintain the state data for any or all satellites, a scenario, and the routing to that particular scenario and satellite(s). The data manager service 120 may be a repository of observations, satellites, satellite states, etc. In various embodiments, the frontend can advantageously combine these different services to produce a compelling narrative (e.g., to create one or more scenarios, to import satellite(s) and state data from the data manager service 120 and then inject that data into the SIM API 170 instance to execute a scenario either for training, tactics development, or an actual mission with real satellites).

Digital space range includes characterization and configuration of operators and/or residence-based objects, among other components, using sensors, payloads, observations, and/or other elements that have been developed and simulated in a simulation environment. Advantageously, it is possible (e.g., using the shared simulation environment and its components) to run the simulations anywhere geographically, including within an ITAR approved location, and have the differing locations interact. Different locations may have different teams (e.g., white, red, and blue, which may be referred to as cells) and they may compete together in a shared environment.

With respect to the multiplayer capabilities, this functionality may include 1v1 or n v n (e.g., multiplayer versus multiplayer) teams from any ITAR-compliant location in the world and a scenario/game browser may be provided that allows custom scenario creation and private/public hosting. The battlespace may advantageously provide network synchronized time (e.g., a client clock may be auto synced on scenario load) and a team-based database (e.g., where each team is assigned read/write access to separate authoritative sources of truth where only the white cell has override ability to the truth and team databases). A physics engine may be provided that is a team-based physics engine (e.g., each team may be assigned a different propagator to emulate team/country fidelity) and there may be networked objectives (e.g., each team/player may be assigned custom objectives). Additionally, team and player progress/completion may be tracked digitally and may use a leaderboard. Success criteria may be dynamically assigned to global and team-based objectives and scenario performance reporting may be automated. Advantageously, embodiments may include player versus computer capabilities for multiplayer features where team (e.g., red team) behaviors at the constellation/unit level, driven by AI. Player roles may be assigned per team and replay functionality may allow return to a previous state in the scenario to branch alternative decisions, as described herein.

In some embodiments, a white team may be referred to as the white cell and it may be an administrative cell that has the ability to view and set all criteria in the environment, including state estimation (e.g., the white cell may view and control state estimation and state estimation libraries). One or more teams, e.g., the red cell, may have better technology in terms of types of objects and properties of objects (e.g., satellites) and more accurate state estimation, or less accurate state estimation. Advantageous embodiments of the present disclosure may include aerospace applications, where the simulation environments include the functionality and components to run aerospace simulations (including the wargaming simulations) across geographically diverse locations. In some advantageous embodiments, because the backend of the system disclosed herein handles the state in a centralized place, this makes it unnecessary to have to sync clocks or state from any individual clients that may be dispersed in diverse locations. This is advantageous because it is difficult to manage clocks on different servers (e.g., it is difficult to determine how to know when one thing happened before or after another, or even in relation to another (e.g., lamppost clocks, vector clocks, hybrid logical clocks, etc.)). The ability to have a single clock that pushes updates, as disclosed herein, provides improved solutions to these problems.

In various embodiments, only one clock may be relied upon (e.g., using the server running the simulation(s), which is managed by the white cell). For example, using clock sync, the white cell may enable a player to join the environment and for the player's scenario to be synched with whatever clock the master timekeeper has. In some aspects, the different cells may have varying permissions and/or varying roles and even different operators or players (e.g., individual team members) may have different permissions and/or roles. For example, if an engagement is simulated with 50 jackal objects and there are 75 adversarial satellites, control may be varied for some sets of like objects (e.g., control of five satellites) where other sets of like objects are under a different control. Thus, some advantageous embodiments enable improved granularity of control within the simulation and/or granularity of information within the scenarios (e.g., statistics such as a number of vehicles that were lost or destroyed, the amount of delta V, and/or the amount of fuel that you spent, among others). The statistics may include agent and human component statistics as well, including if using an immersive digital facility. For example, a dedicated facility may be provided where operators can train or tactics can be developed. Advantageously, a distinct facility may be used that has a dedicated network for high reliability and performance. Illustrative examples of statistics may include a leaderboard to encourage competition, or more detailed statistics that show an operator's skill development over time through various metrics like delta V used, faces of a satellite (including adversary satellite) imaged, number of maneuvers to accomplish a goal, time to accomplish a goal, number of assets protected, number of adversaries destroyed or disabled, time to respond to a launch, time to launch, etc. Thus, advantageously, when training, it is possible to collect and summarize the data at a granular level where it is advantageous to monitor statistics and progress (e.g., for use with a scoring mechanism). Such advantageous embodiments can improve training by providing improved information to users being trained in order to improve their knowledge and skill level (e.g., to a higher skill level, to provide greater knowledge, to improve judgment, to train faster, etc.).

Turning now to space data management, the system may comprise a catchable responsive space or tactical command and control. For example, an adversarial nation may launch a rocket with satellites, and space data management may help determine how to respond to that while advantageously using a simulation environment. Thus, a model for launching at launch sites may be simulated. The model may simulate an incident response for a timing of when the object(s) (e.g., a satellite) is on orbit, and the model may help determine how to respond (in some embodiments, determine if there are satellite derived assets on orbit that have the ability to respond to the launch, or is it necessary to launch other assets). Part of the simulation can determine the speed (e.g., how quickly) at which the response can occur. In some advantageous aspects, this is helpful; e.g., if an adversarial nation makes a threatening maneuver towards a high value asset, then it is possible to determine how to respond. Thus, advantageous applications of the systems and methods disclosed herein may include scenarios of responding to an adversarial nation, as well as scenarios including on-orbit objects (including combat or defensive operations). These scenarios may occur in real-life, may be simulations of real-life, or may be gaming only.

Turning to types of tactical decision aids, these may include, for example, residuals, visibility windows/access times, transfer/intercept porkchop plots, covariance, point of close approach, camera to sun angle, range rate, and reachability analyses and visualization. In some embodiments, tactical decision aids may include aspects such as covariance tools (including determinations of likelihoods for locations of objects including in-orbit objects) and other tools that may help operators (e.g., pilots and AI pilots) to be able to determine improved decisions. Tactical decision aids may include not only software but also visual overlays and tools that perform calculations in the background in real time in order to advantageously update information provided to the operator (e.g., a heads-up display). Tactical decision aids may include charts as well as other tools that are static and/or dynamic in nature. For example, some tools may show that, for a given airframe, an energy maneuverability plot displays details of the airframe such as whether it is possible to achieve an altitude and/or an airspeed at a certain altitude. Tactical decision aids include providing information on range rate, which refers to the rate at which a range to another object is changing. Range rate information, in some aspects, may include a tool that, for a given object, provides the curves of range rates that an operator may want to consider for a safe approach to an object, which may be overlaid with other information such as the range to the object and how to adjust a range for a desired result. Tools such as range rate may be advantageously useful for reachability analyses and launch window analyses.

Transfer analyses may be another tactical decision aid. Transfer analysis information provides information such as how to visualize an amount of fuel needed to perform a certain maneuver at a certain time.

Various embodiments of the present disclosure provide tools that advantageously involve and/or model live operations. For example, the battlespace mode may be a multiplayer type of environment for humans to interact within and space battle management may have capabilities similar to an Airborne Warning and Control Systems (AWACS) aircraft. In various aspects, when managing an entire battlespace, a lot of units going around the digital range may be more similar to a machine simulation environment. For example, if you have a satellite model that you want to incorporate and see how it performs against other satellite models, it is possible to use an offline analysis (e.g., including Monte Carlo analyses). Advantageously, this may provide information about many trajectories, and tradeoffs of performing different maneuvers at different timings. It is possible to perform analyses on maneuvers across an entire envelope of possibilities. Many of the tools described herein (such as battlespace, digital range, launch window modeling, and satellite modeling) are available across all the modes (e.g., environments). For example, launch window modeling may be used in the space power management mode and also in other modes if needed. Advantageously, these tools may be chosen and used based on the focus of the simulation(s) and the arrangement of the default interfaces that are needed when you access various modes.

Various modes, or portions of modes, may exist completely within the scenario manager, data manager and use one or more of the same APIs. Some modes may use additional components, such as ground station as a service and command and control. Some modes may use same backend components and have different features that are exposed. Various modes may embed or use AI pilots, such as some or all of the tactical decision aids.

In various embodiments, loading a scenario may mean that certain information is requested and sent to the backend (e.g., to the scenario manager service) in order to create a new record in one or more databases based on the name of the scenario and some other metadata. The scenario manager service may then call to an unallocated instance of the SIM API (e.g., in the pool of SIM APIs), which then assigns it to the scenario for the life of that scenario. At this time, the simulation may be initialized in the environment. After this time, it is advantageously possible to adjust the scenarios (including capacity, conditions, astrodynamics information and measurements, and/or states of object(s), among others) as disclosed herein. For example, it is possible to continue to spawn satellites while a scenario (e.g., a mission) is running. Also advantageously, it is possible to speed up the scenario or increase the speed of the simulation. By way of example, it is contemplated that a user may be able to project forward in time and scrub time back and forth in that projection.

Various embodiments provide different frames (e.g., different views) such as a UCI view, an Earth centered inertial (ECI) frame, and a latitude, longitude and altitude frame. Additionally, it is possible to use commanding and telemetry interfaces, which may be the same or similar to what is needed for real-life satellite operations. These may be implemented using, at least in part, various external tools as discussed herein.

Aspects of the present disclosure are provided through the GUI. For example, if a user wanted to perform a launch window analysis, the user would proceed through the menus to select options in the GUI and perform the selected options. However, the modeling and simulation libraries (e.g., components available in the back end) could be available to a user who wants to work in a Python scripting environment. Thus, the user could call all of the same functions that the GUI can call but from the script environment. For example, if they wanted to perform a batch analysis of thousands of launch window simulations, they could advantageously speed up the process by batch scripting the analysis in a selected language (e.g., Python).

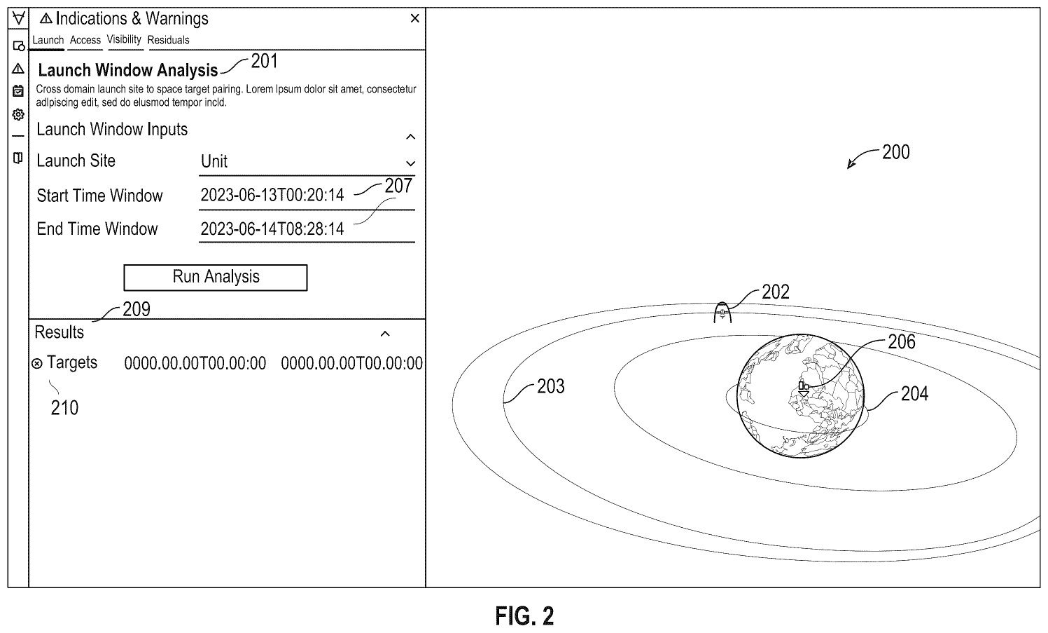

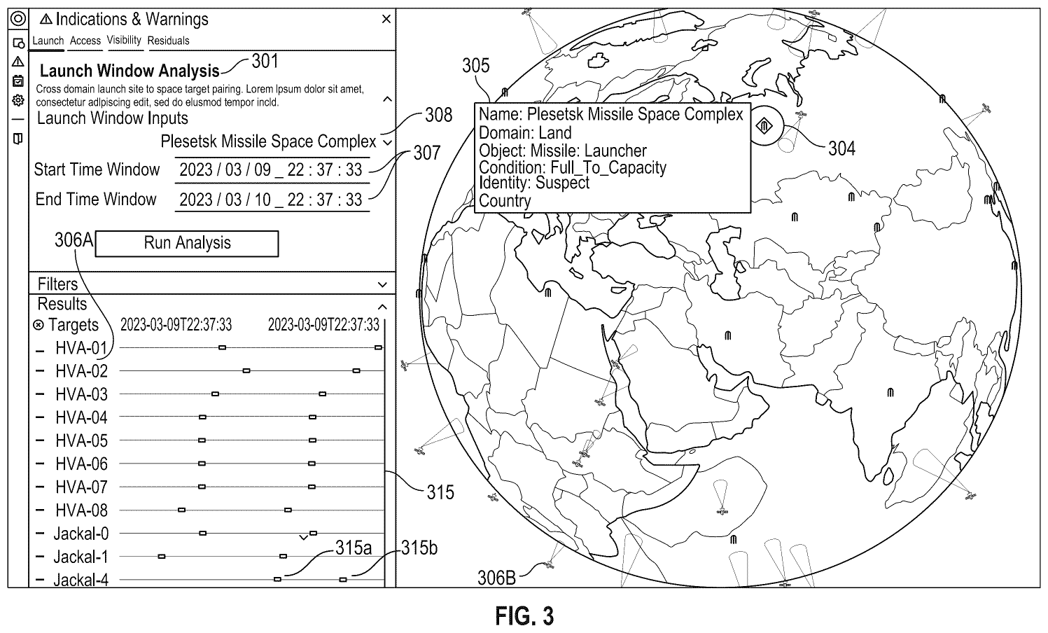

FIG. 2, in various embodiments, shows a view of an illustrative launch window analysis 200 in accordance with at least some embodiments of the present disclosure. For example, FIG. 2 shows examples of generating launch windows in an inertial frame view. In some aspects, this view may show all objects around Earth, or less than all. In other aspects, this view may show all or only selected objects within a solar system. FIG. 2 shows a launch window analysis 201 being configured (e.g., with launch window inputs 205) with one object 202 in orbit (e.g., the elliptical line) 203 around the planet Earth 204. As one example view of the launch window analysis, the system may show different objects (e.g., targets, such as satellites), which are in orbit. The viewing of the different objects may assist in collision avoidance. Additionally, the system may select a launch site to determine which launch windows may direct inject a target into the same plane as the object that is in orbit. In some aspects, the information provided in this illustrative view may result in launch windows (not shown, see FIG. 3 for illustrative launch windows) following execution of the launch window analysis. In further embodiments, the information provided in this illustrative view may show a simulated launch and injecting objects. In various embodiments of FIG. 2, information entered into the launch window analysis 201 may be sent to the M&S API 110 and the components of the M&S API calculate results 209 based on the inputs (e.g., time window 207 and launch site 208) together with the scenario information stored within the M&S API 110. The results of the launch window analysis in FIG. 2 are then sent from the M&S API 110 to the PVI 130 where it is configured and displayed to the user as the results 209 (e.g., targets 210) in FIG. 2.

The view of FIG. 2 may include showing an analysis of a constellation state of health (e.g., using color indications of health, such as green, yellow, red). At least portions of this view may be considered to be a “birds' eye” view (e.g., showing planet Earth 204 from a high angle). If this view is configured to show a working status (e.g., using a working mode), an operator may use the system in this view to act as a white cell in order to manage (e.g., add and/or remove) vehicles from the simulation and monitor the status of elements of the system (e.g., objects, players, and/or other elements, such as launch site 206, object 202, etc.).

A white cell may be the exercise controller (e.g., coordinator, referee, etc.) who has managing privileges. Thus, the white cell may set up the scenarios, control one or more clocks (e.g., the system clock and/or player clocks), and have access to the absolute truth of the system including knowing the existence and locations of everything in the environment. As discussed herein, the white cell may be controlled by scenarios managed by the M&S API 110 in a cloud-based system, which advantageously provides improved speed of functionality and ability to control clocks of the system. Thus, although each player has only their own view of the environment because they each have access only to information from their own sensors and are limited to their individual state estimation process, the white cell may have access to all information, including every player's information. The white cell may have privileges to modify any data in any of the databases in order to change objects, team/player capabilities, and any other information, if necessary.

In various embodiments, to provide the functionality shown in FIG. 2, certain information (e.g., launch site 208 and time window 207) may be requested and sent to the backend (e.g., to the scenario manager 101) to load a scenario by creating a new record in one or more databases based on specified scenario information and any other metadata. The scenario manager 101 may then call to an unallocated instance of the SIM API (e.g., in the pool of SIM APIs), and then assign the SIM API to the scenario for the life of that scenario. At this time, the simulation may be initialized in the environment. The launch window analysis (also referred to as launch window modeling) shown in FIG. 2 may be available across any of the modes disclosed herein. For example, launch window analysis may be used in the space power management mode and in battle management (e.g., to assist in determining how to respond to an adversary). Advantageously, these tools may be chosen and used based on the focus of the simulation(s) and the arrangement of the default interfaces that are needed when you access various modes.

In various embodiments, to provide the functionality and view of FIG. 2, the scenarios may be managed by, for example, a scenario manager (e.g., scenario manager 101, which communicates with telemetry and commanding service 160). To run the analysis, for example, a physics engine (e.g., modeling and simulation API 110) determines simulation information, which is sent to the PVI 130 where it is combined with information from the scenario manager 101 and presented to an operator. In various embodiments, the “universe” that is rendered in FIG. 2 is from the SIM API 170 and the SIM API 170 is controlled by scenario manager 101 which makes use of event logger 102, CMD/TLM manager 103, scenario replayer 104, and mission modules 105. In some aspects, if the object is a live asset then it may verify ground C2 159, AI pilots 140, and telemetry and commanding 160 to send data to the SV and to receive and store telemetry. Encode/decode 182 is for encryption and decryption, which may be used for a live SV. For example, launch analysis may use SIM API 170, which is the embedded simulation and physics engine that exposes the functions that do launch analysis.

Thus, in FIG. 2, a specific launch site 206 (e.g., Missile Space Complex) may be selected with a time window 207 to run the launch window analysis and receive results 209. Further illustrative results of the launch window analysis are shown in FIG. 3.

FIG. 3 shows a view of an illustrative launch window analysis 300 in accordance with at least some embodiments of the present disclosure. For example, in FIG. 3 a specific launch site 308 (e.g., a missile space complex) has been selected under launch window inputs. FIG. 3 shows generated launch windows 315, which are based on the timeframe 307 of Mar. 9, 2023, to Mar. 10, 2023 (e.g., a time window 307 of “2023 Mar. 9 22:37:33” to “2023 Mar. 10 22:37:33”). The generated launch windows 315 indicate which assets would be vulnerable to a direct inject launch during timeframe 307. In some aspects, the launch windows are indicated by the space between the bars (e.g., bar 315a and bar 315b) (which are on the lines to the right of each target (e.g., HVA-01, HVA-02, etc.)) that correspond to the time(s) that the vulnerabilities occur.

In FIG. 3, properties 305 of the launch site are displayed next to the launch site 304 correspondingly shown as selected on the view of the Earth. In various aspects, FIG. 3 may also show some or all of the assets that would be vulnerable to a direct object launch, which in this screenshot include high value assets (HVAs) 306 (shown only as 306A-306B for clarity, with only one HVA in the list of Results 306A and one HVA in the inertial frame view 306B being labeled) and other objects (which in some instances may be shown in color such as blue and red), among others. In various embodiments, colors of objects may provide an indication of their properties, e.g., green objects may be considered to be neutral objects (such as commercial telescopes, launch entities, etc.); blue objects may be considered to be Allied (e.g., good) objects, and red objects may be considered to be threat objects. In FIG. 3, space between the bars (in some instances these may be white bars) show the times at which the objects could be vulnerable to a direct object launch. One set of bars is labeled for illustrative purposes as bar 315a and bar 315b.

In some instances, a bar may be selected (e.g., with a right click) and a user may also select an action (e.g., to simulate a launch). For the simulated launch, the system could inject another object in the simulation in plane with any target that was selected. In various embodiments, the M&S API 110 may input data at a compile time to simulate the changes to the scenario (e.g., injecting an additional object) that is stored in the scenario manager 101 using a SIM API instance 170 associated with the relevant scenario. In some aspects, operators may view and interact with the components of FIG. 3 (similar to the other screenshots shown and/or described herein) using the PVI 130.

In some examples, the analysis shown in this illustrative view may be used to determine and show an intercept analysis (e.g., how to get an object to a desired plane, how to get one object within a certain distance of another object, and/or how to have one object intercept another object, among other objectives). In further examples, an operator may configure the launch window analysis to show different objects, which are in orbit and may select a launch site, such as a ground system, to determine which launch windows may direct inject a target into the same plane as the object that is in orbit. In some aspects, the information provided in this illustrative view shows launch windows and in further embodiments, the information provided in this illustrative view shows a simulated launch and injecting objects. Various results of this view show inertial results of launching objects and the results can advantageously be shown in different types of frames.

In some embodiments, as a method of the launch window analysis, a timespan is assigned, one of more target units are assigned, one or more launch sites are selected, and the analysis is conducted. When a launch site is selected, in some aspects multiple launch sites may be selected. Launch sites may be selected based on certain properties (e.g., all launch sites within a specified geographic area may be selected based on their geographic location within the geographic area). In some embodiments, a specified geographic area may be selected, and the launch sites located within that area are automatically selected to include in the launch window analysis. The results of the analysis show, for example, the time window in which an object can be launched from the one or more sites in order to meet any specific objective(s) desired, such as launching an object during a certain timeframe into a particular orbit while avoiding other objects.

The launch window analysis may also be useful from a threat perspective. For example, if there are launch sites associated with threats (e.g., launch sites located in countries that that may be considered adversarial), it may be desirable to determine when one or more assets are at risk of a launch from that geographic area. In some instances, it may be desirable to determine when it is possible for the adversarial site(s) to inject an object into a same plane as another (e.g., friendly) object. These windows could be determined using the launch window analysis as described herein. With respect to FIG. 3, the launch windows may be determined by the space between the bars (e.g., bar 315a and bar 315b) associated with each target.

As one illustrative example of a use of the launch window analysis, multiple analyses could be performed. For example, using the M&S API 110 together with the relevant scenarios saved in the one or more SIM API instances 170, the system can execute a simulated launch of a red threat object into a plane with a communication satellite (which could be an actual communication satellite or one that has not yet been launched). The analysis could be performed using the system to model that object in space (e.g., in orbit) with the analysis data shown visually by the PVI 130. More than one object may be launched so that there are multiple objects (e.g., multiple red and/or blue and/or other objects) in orbit and all objects (and various associated properties such as their domain, object type, condition, identity, and country) may be displayed by the PVI 130. It is also possible to run another analysis from a friendly launch site to determine when it is possible to launch, and where to launch from, in order to rendezvous with any one or more objects (e.g., the red threat object). Other properties associated with the objects and launches may be determined by the analysis, such as how much fuel it may take to rendezvous with one or more threats. Thus, in various embodiments it is possible to combine multiple launches into one or more scenarios and into one or more views.

In further embodiments, it is possible to run one launch at a time. For example, a red launch would be simulated, and then after the red object is launched, a blue launch would be simulated to launch a blue object. The system can provide sets of features. For example, the system can provide features that show timeframes that are a launch window analysis of timing for when to launch objects to achieve a certain objective (e.g., location on a specified plane in orbit, a desired interception of one or more objects, etc.). Additionally, in some embodiments, the system provides features that simulate the launch (and any additional launches) and injects the object or objects in orbit. These sets of features can be connected together (e.g., using the scenario saved in one or more SIM API instances 170), then the system may put the object(s) in orbit (e.g., by processing in the M&S API 110), and a user is able to see the object(s) in the frames using the PVI 130, such as the frame shown in the screenshot of FIG. 3. The mission manager 150 and AI pilots 140 may enable the functionality of FIG. 3.

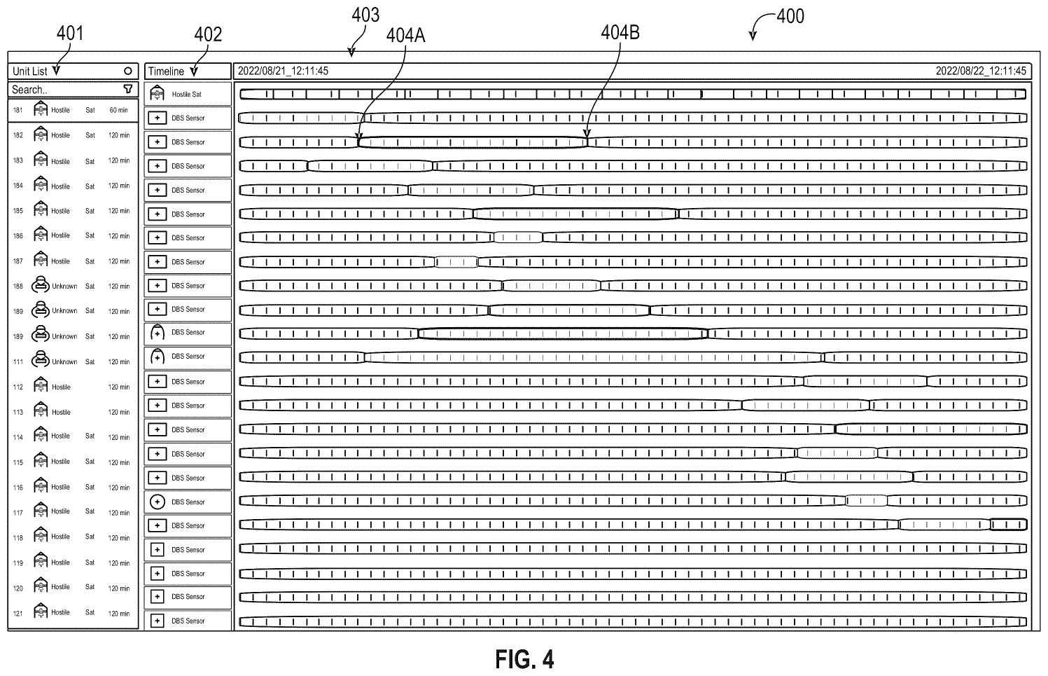

FIG. 4 shows a view of an illustrative sensor scheduler and visibility windows 400 in accordance with at least some embodiments of the present disclosure. Similar to other screenshots shown and/or described herein, the components of FIG. 1 enable the functionality of the operator interface. For example, FIG. 1 is the data, physics, and computational layer that is rendered as appropriate by FIG. 4 through APIs that return data in FIG. 1. The information shown in FIG. 4 may be calculated by the M&S API 110 and provided to the PVI 130 for display. In some embodiments, FIG. 4 shows windows of Timeframes 402 for visibility of various objects. The objects shown in this view are listed in the Unit List 401 and the Timeline 402, which is shown to the right of the Unit List 401. In this embodiment, the Timeline 402 provides a list of sensors and their visibility (as windows of time 403 that are shown as a set of bars (e.g., tick marks) located between time stamps 404A and 404B) associated with a selected object (the selected object is not shown in FIG. 4). For example, Timeline 402 shows visibility windows (e.g., 403) of a space target against a number of ground and space sensors, where each row depicts the visibility window where both the sensor and the target are within line of sight. The ticks (e.g., illustratively labeled ticks 404A and 404B) represent the capacity of each sensor to collect a number of observations. Using this dashboard the operator may set a revisit rate for the target and the system could advantageously calculate and schedule the sensor pairs that could maintain that capture rate.

As a further example, FIG. 4 could be used by an operator to determine visibility of certain objects (e.g., telescopes and communication antennas around the planet) to see what time windows that there would be visibility between the antenna(s) and/or telescope(s) to a selected object in space. In other words, using only one unit as an example, the bars on the right of the Timeline 403 between the time stamps 404A and 404B show an amount of time (e.g., a time window) when a selected object (not shown) will have visibility from that the selected object's location to the one unit. The list of units 401 in FIG. 4 show the different time windows when a selected object (not shown) will have visibility from that the selected object's location to each specific unit (e.g., target) shown in Unit List 401. In some aspects, the Timeline 402 may provide additional information, such as icons indicating additional detail about the objects (e.g., what type of objects they are, among other information). Embodiments of FIG. 4 may be associated with the Modeling & Simulation API 110, Threat Warning & Assessment 131, Orbit Management 174, Data Manager 120, and Commercial Data Providers 191.

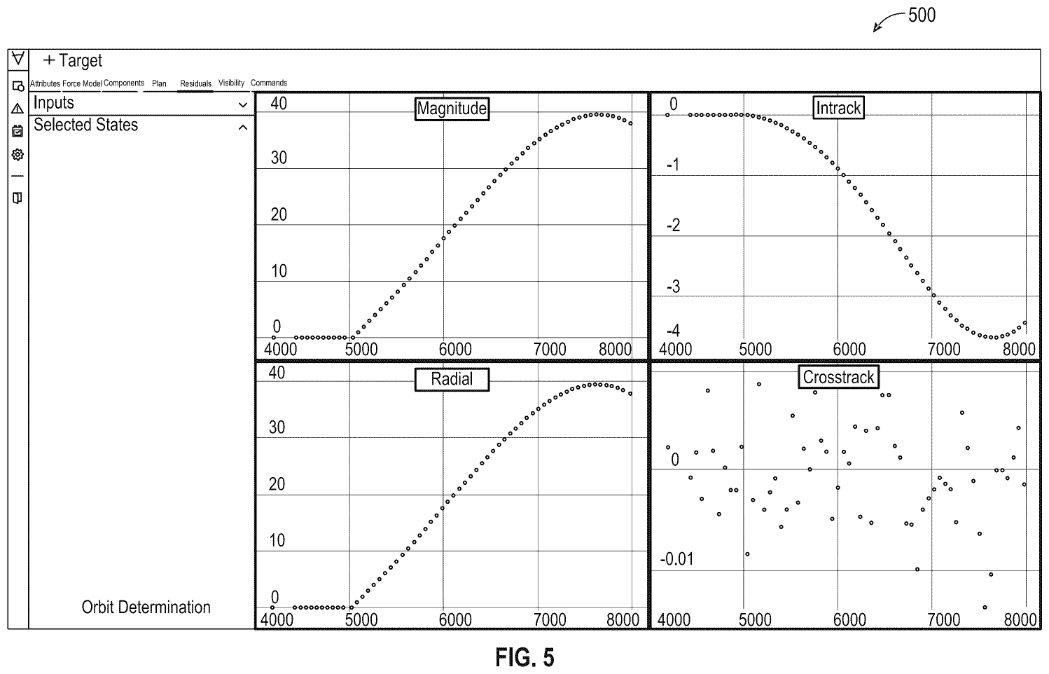

FIG. 5 shows a view of an illustrative residuals analysis 500 in accordance with at least some embodiments of the present disclosure. The information shown in FIG. 5 may be calculated by the M&S API 110 and provided to the PVI 130 for display. In various aspects, FIG. 5 shows differences between real time measurements for an object's location and movement and model estimates of the object's location. For example, when an object has an onboard sensor package (e.g., which may include cameras and/or radar, among other sensors) and possibly other equipment to monitor positional data, and the object is directed to find and track on a specific target (which could be an aircraft, spacecraft, etc.), it may observe the specific target and perform a process known as state estimation.

In some aspects of the state estimation process, measurements are taken, and the object calculates one or more estimations of the state data of the specific target that it's monitoring. The object may have both a model onboard (e.g., a mathematical model of the specific target) that provides one or more model estimates, as well as actual real-life observations of the specific target. The real-life observations may include data that is monitored in real-time, such as by external sensors. The systems of the object may subtract the real-time measurements from the model estimate(s) to determine what the specific target should be doing or other properties of the specific target. In various embodiments, the difference between what is calculated is called the residual. As shown in FIG. 5, this view of residuals over time shows variances in the residuals. Thus, in areas where the residual is very low, this means that the model estimate(s) and the real-time measurements line up well (e.g., provide similar results, in other words the difference is small). However, as residuals get larger, this means that the model estimate(s) are not tracking well with the data from the real-life measurements (e.g., the difference is larger).

In various aspects, FIG. 5 depicts part of the State Management workflow that pertains to Observations (OBS), Residuals, and Orbit Determination. OBS may be collected by sensors targeting Resident Space Objects (e.g., RSOs). A data manager (e.g., data manager 120) stores the OBS and the PVI (e.g., PVI 130) displays them on residual graphs. Each graph represents a delta value of the OBS against the assumed location of the RSO. In-track may be along, or essentially along, the velocity vector, Cross-track may be, or may essentially be, the elevation angle, and Radial may be, or may essentially be, the altitude. In some embodiments, if the track becomes old (e.g., out of date or that the RSO has drifted) or the RSO has maneuvered, operators can select the OBS on the graph and perform a best fit solve called Orbit Determination. After a solve is performed, the graphs would flatten assuming the new state and OBS are aligned. The residual analysis 500 may be provided as an indicator of what is happening with the specific target, which can be advantageously useful in a mission plan or as information provided to an operator, e.g., giving them advance notice of changing states of objects (such as the specific target). The operator, or anyone involved with the mission plan, for example, may therefore have an initial cue that some kind of action needs to take place or decisions need to be made. The actions and/or decisions may include determining additional detail about what is happening with the object(s), if the data is accurate, and/or if there is an issue with any of the systems. Therefore, advantageously, residuals analyses (such as that shown illustratively in FIG. 5) may aid in making tactical decisions about objects. Features of FIG. 5 may be associated with Orbit Determination 172, Orbit Management 177, Data Manager 120, and Commercial Data Providers 191.

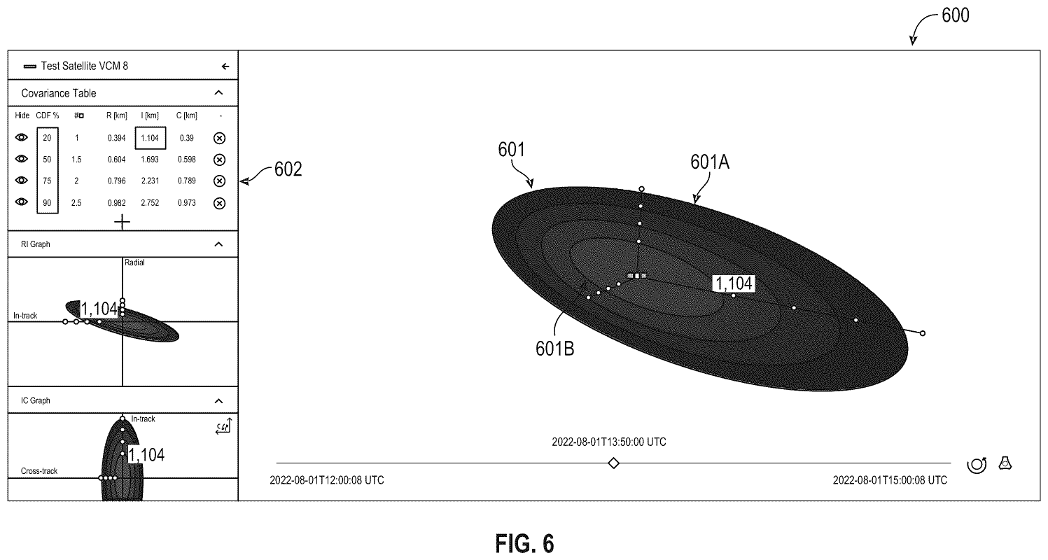

FIG. 6 shows a view of an illustrative covariance analysis 600 in accordance with at least some embodiments of the present disclosure. In some embodiments, FIG. 6 shows covariance, which determines an accuracy of position by accounting for different error sources, such as atmospheric interference or sensor noise. In various aspects, covariance is related to the residual and state estimation process. For example, when the position of an object in orbit is estimated using external sensors and other information, there is some variability in the results. In other words, the location may not be exact. Thus, a volume may be provided, and the calculations may show the covariance (e.g., probabilities of the objects location within the volume). The information shown in FIG. 6 may be calculated by the M&S API 110 and provided to the PVI 130 for display. In some aspects, FIG. 6 operates via SIM API 170 and M&S API 110 (including orbit propagation 117 to visualize the orbit), orbit determination 172, and covariance modeling 135 (e.g., for the rings are around the satellite).

In various embodiments, FIG. 6 shows covariance plotted visually where the different shades of the bubbles (e.g., the elliptical shapes 601) show the cumulative distribution functions (e.g., the probability that the object exists within each of the elliptical shapes 601). In the presently illustrated view, the outermost ellipsoid 601A has a 90% probability that the object is within its shape, and the probabilities decrease as the elliptical shapes get smaller so that the smallest elliptical shape 601B has a 20% probability that the object is within its shape. Additionally, the view may show other data 602. For example, this view shows a radial radius for the largest elliptical shape 601A of about 1 km, and a radial radius of the smallest elliptical shape of about 0.4 km (with the radial radius being measured using an in-track/cross track orientation). FIG. 6 may be associated with Covariance Modeling 135.

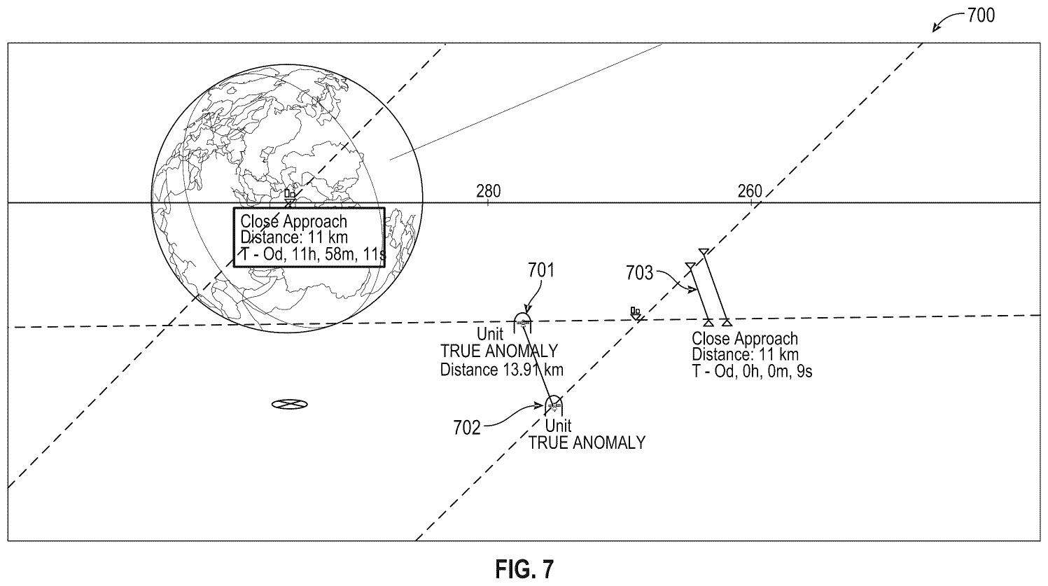

FIG. 7 shows a view of an illustrative Point of Close Approach 700 in accordance with at least some embodiments of the present disclosure. The information shown in FIG. 7 may be calculated by the M&S API 110 and provided to the PVI 130 for display. FIG. 7 may operate via SIM API 170 and M&S API 110 (including orbit propagation 117 to visualize the orbit), orbit determination 172, and conjunction analysis 175. In various aspects, this view shows future points for two objects (e.g., object 701 and object 702) that are propagating around different orbits and when they will have the closest range 703, based on orbital mechanics. Additionally, this view may show objects (e.g., object 701 and object 702) within a planned maneuver and where they have the closest range 703, based on orbital mechanics. This view may show where, when, and what the range is between the objects. For example, for the two objects shown in this view, the range is 9 seconds and the point of closest approach (e.g., POCA) is about 11 km.

For example, the system may send the commands out through scenario manager 101 into the command-and-control component (e.g., Ground C2 159), which would manage the commands as necessary. The command(s) may communicate directly to the spacecraft (e.g., if it is a basic command) or the command may be a sequence of commands. In some embodiments, the command may be a sequence of commands that use a scripting language such as FlightJAS and are communicated to the ground stations (e.g., the service provider). Still further, it is contemplated that the commands may be sent out over WebSockets and may then be communicated to a satellite. Furthermore, the commands may be communicated to another system and translated into the relevant protocol and then communicated to the satellite. The satellite may then decode and decrypt the commands, which are then read by the satellite and telemetry data may be communicated

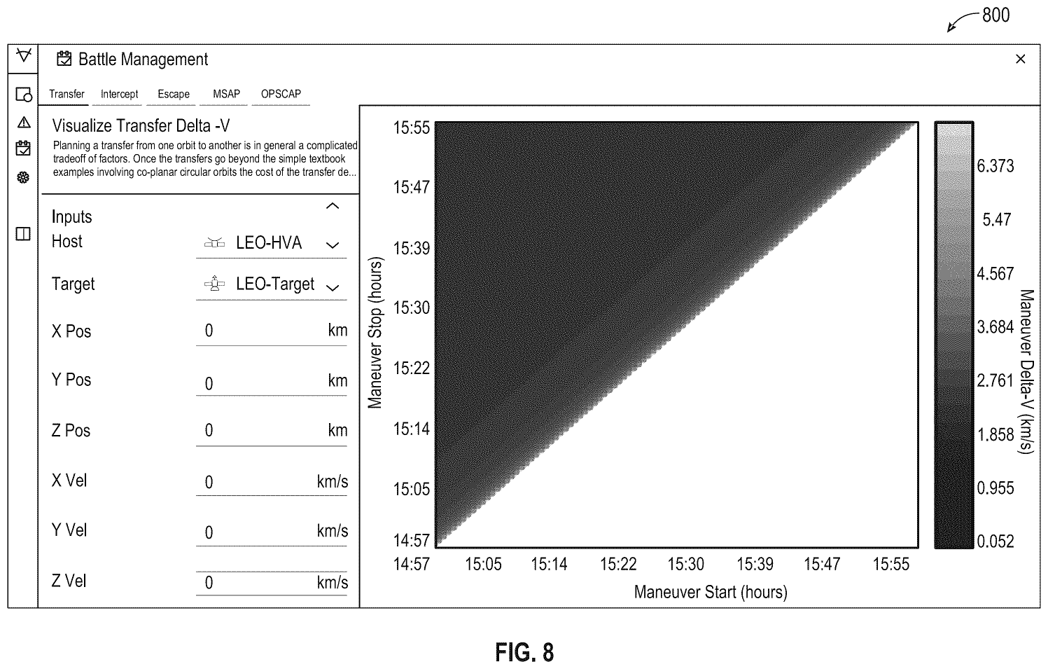

FIG. 8 shows a view of an illustrative transfer analysis 800 in accordance with at least some embodiments of the present disclosure. The information shown in FIG. 8 may be calculated by the M&S API 110 and provided to the PVI 130 for display. In FIG. 8, two vehicles are selected as well as a point below a desired arrival location and conditions are specified (e.g., an operator may specify xyz position(s) and xyz velocity constraints that are imparted upon the host arriving on the target, where xyz is a placeholder and can be inertial or it can be radial in-track/cross track positioning) in order to visualize transfer delta-v. On the right-hand side, this illustrative view shows a starting time (e.g., when the maneuver starts) relative to an absolute value and when the maneuver stops is on the y-axis and the color scale shows how much the maneuver would cost. The bottom right, the black indicates that those are timing options that are not feasible based on some constraint that is set. The yellow line diagonally across is the limit of possibilities to maneuver. The area above the line shows start and stop at furthest point in the future possible and this is the cheapest option, and as the maneuver stop is made sooner in the future then the cost goes up until it reaches the maximum possible cost. This allows a view of the span of possibilities for maneuvering for these two vehicles. In various embodiments, FIG. 8 shows a space-to-space intercept analysis, where the x-axis is the departure time, the y-axis is the arrival time (or time of intercept), and the heat map value is the fuel cost. Features of FIG. 8 may be associated with Threat Warning & Assessment 131, Physics/Dynamics 112, and RPO Planner 113.

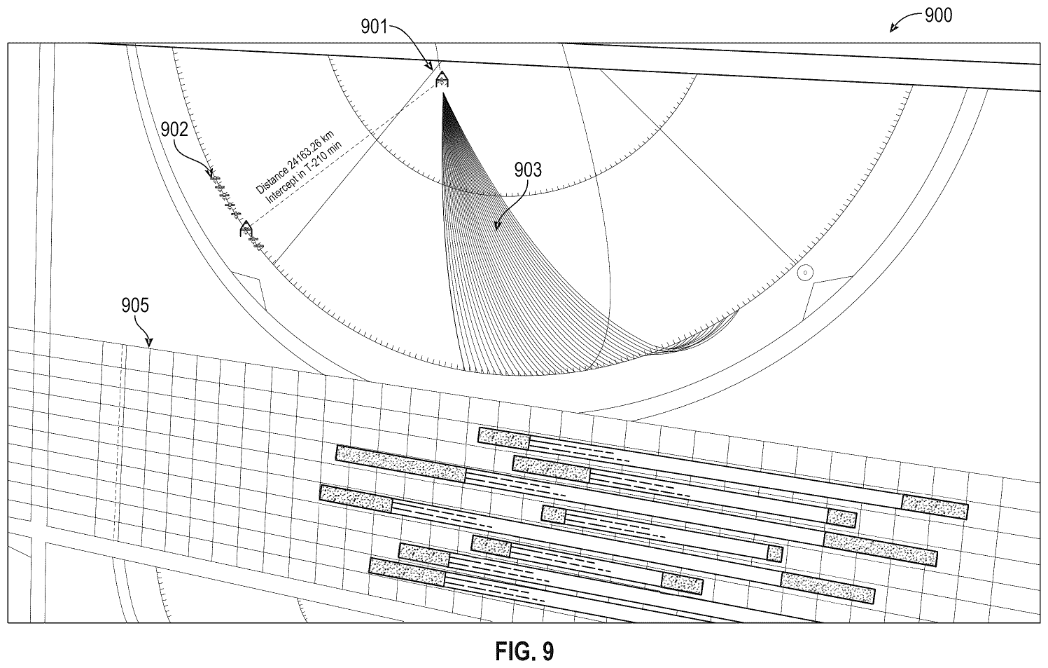

FIG. 9 shows a view of an illustrative transfer analysis 900 in accordance with at least some embodiments of the present disclosure. In various embodiments, this view is a notional render and in various embodiments it is an extension of FIG. 8. In some aspects, FIG. 9 shows the susceptibility of intercept from a Direct Ascent ASAT (DA-ASAT). For example, in the 3D scene, the ASAT's trajectory splits into viable paths based on the assumed fuel budget of the missile and the time of flight (TOF) to intercept any of the scene's HVAs. FIG. 9 shows information for multiple vehicles 902 (e.g., multiple targets) as they relate to another vehicle 901 (e.g., a launched vehicle, and/or a threat vehicle, etc.). In this view, there is a vehicle at the top of the view 901 and then there are multiple targets 902 and the trajectory lines 903 show the span of possible trajectories (e.g., the results of the transfer analysis) for vehicle 901 to reach any of vehicles 902 (e.g., the lower half of the screen shows a timeline view of the missile to target pairings and each of their intercept windows).

In some aspects, the tool shown in this view helps an operator understand which of these vehicles shown on the outer ring 902 may be targeted by vehicle 901. For instance, when the simulation initially starts, the results aren't very clear because there is time for maneuverability (e.g., there is some capability to retarget the objects 902); however, as the vehicle 901 gets closer, then the window of possibilities gets more and more narrow, thereby providing results of the transfer analysis. In various aspects, this transfer analysis may be referred to as a reachability analysis. Additional information may be shown in this view, such as chart 905 showing timing windows for reachability of each of vehicles 902. In some embodiments, the elements shown in FIG. 9 relate to mission planning and its features described herein.

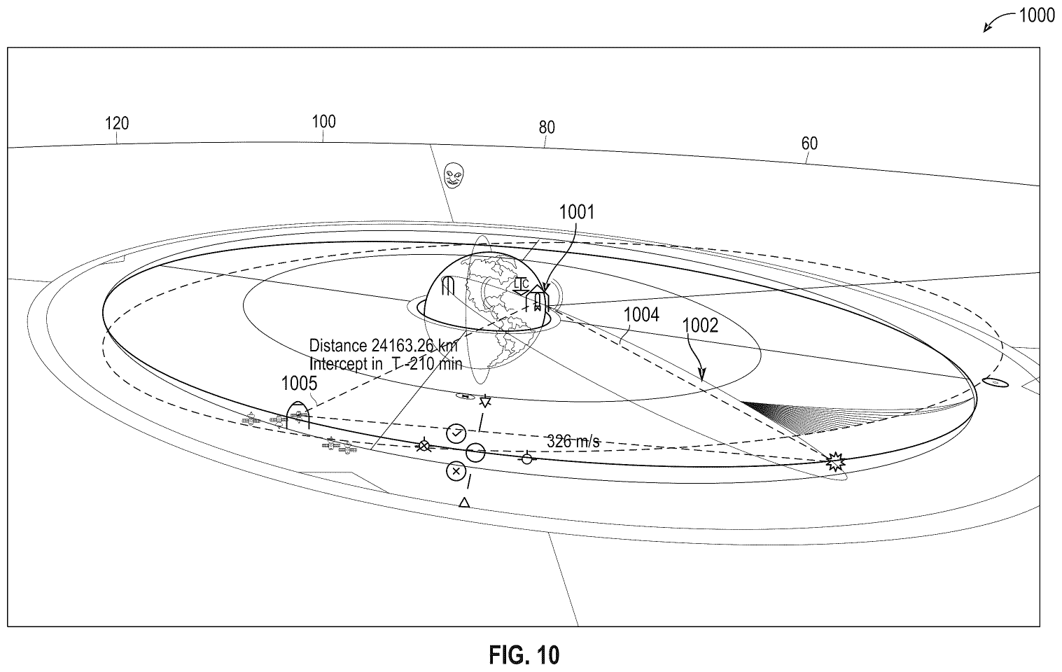

FIG. 10 shows a view of an illustrative avoidance analysis 1000 in accordance with at least some embodiments of the present disclosure. In various aspects, this is another view of a transfer analysis. The information shown in FIG. 10 may be calculated by the M&S API 110 and provided to the PVI 130 for display. This view shows a rocket 1001 launched and its trajectory 1002 is set to intercept an object 1003. Line 1004 and line 1005 each show possible paths for a threat object (e.g., a rocket). This tool may be used for determining what maneuver to make with a vehicle to put it outside of the capabilities of the threat object launched (e.g., here 326 m/s, as labeled in FIG. 10, is one maneuver option to choose to avoid the threat object). In various aspects, FIG. 10 depicts an Earth Centered Inertial (ECI) view of HVAs versus a DA-ASAT. Their inertial (orbit) trajectories are shown (e.g., 1002) and there is a predicted conjunction event (e.g., 1003). Widgets may be used for maneuver planning; For example, a maneuver widget that aligns with the selected HVA's RIC axis, and an escape intercept widget may be presented for an operator's use. Features of FIG. 10 may be associated with Physics/Dynamics 112, RPO Planner 113, Discrete Event Simulation 114, Orbit Propagation 117, Threat Warning & Assessment 131, Launch Modeling 136, Conjunction Analysis 175, and Maneuver Planning 156. FIG. 10, in various embodiments, shows an analysis of a view that corresponds to FIG. 9.

Advantageously, in the example embodiments shown with aspects related to reachability (e.g., in FIGS. 8-10), the system may present information that improves understanding of where energy requirements are performing. For example, an operator may be able to view a span of possibilities more easily and more quickly and effectively understand how to make the transfer/maneuver the most efficient possible.

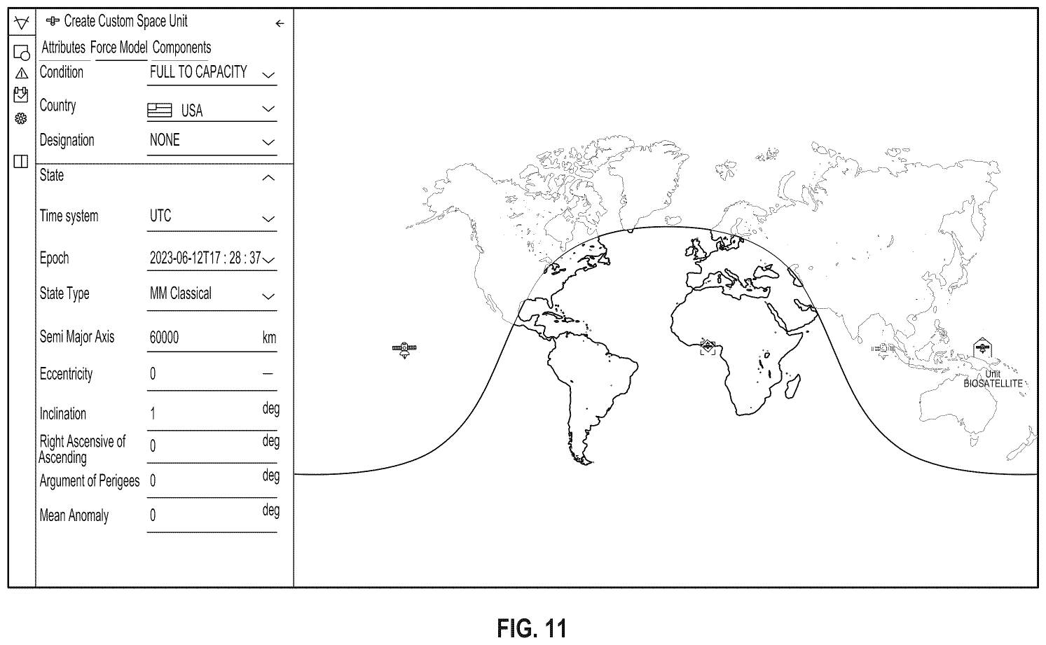

FIG. 11 is a view of an illustrative latitude and longitude view in accordance with at least some embodiments of the present disclosure. In certain aspects, FIG. 11 shows a Latitude Longitude Altitude (LLA) frame. Satellite units may be placed on the map at their relative positions over a fixed Earth. In FIG. 11, the satellites are in GEO so they perch in place along the equator. The LLA frame may be useful when observing satellite ground tracks, and this may allow operators to observe when satellites may fly over certain areas, such as ground stations or mission areas. These features are associated with Modeling & Simulation API 110.

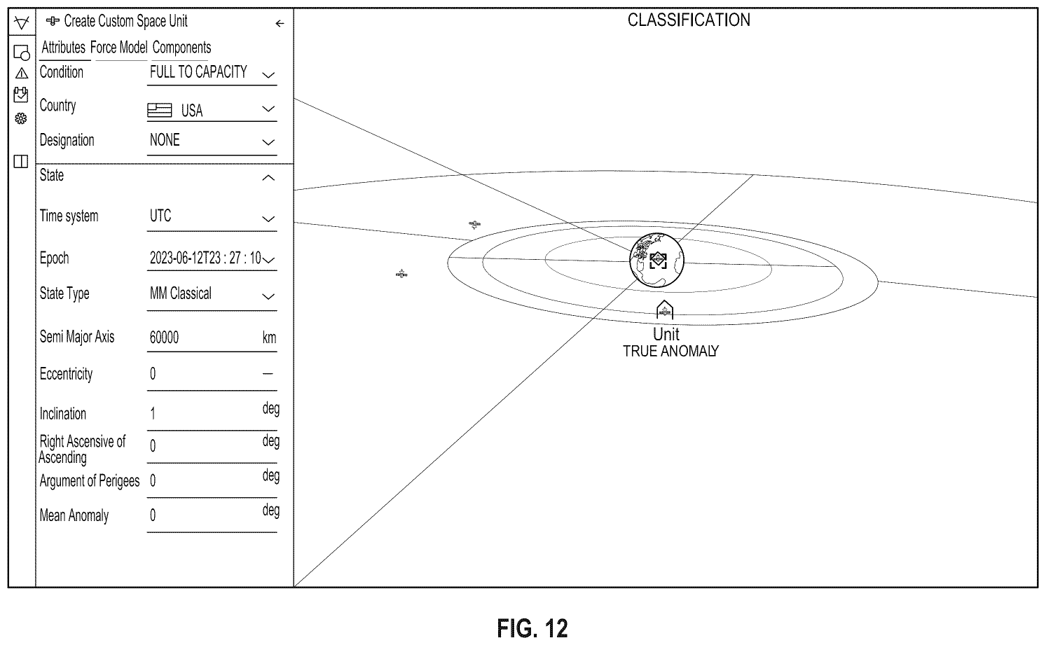

FIG. 12 is a view of an illustrative relative frame view in accordance with at least some embodiments of the present disclosure. In certain aspects, FIG. 12 depicts an Earth Centered Inertial (ECI) frame. Satellite units and celestial bodies may be positioned in a 3D scene relative to the Earth as the origin and Earth rotation axis as world up. For example, in this frame the Earth rotates (1 rev/day) in the center and all propagated bodies orbit the Earth (including the Moon and Sun). The ECI frame may be useful for operators to see the inertial (circular/elliptical) orbits of the satellites. These features are associated with Modeling & Simulation API 110.

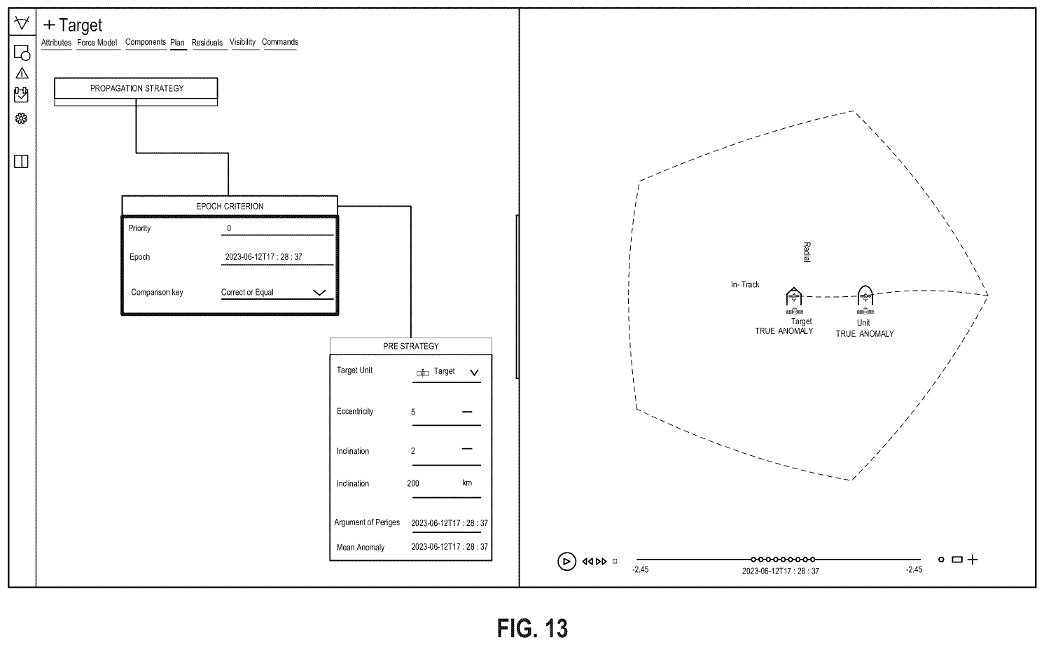

FIG. 13 shows a view of an illustrative development of a maneuver strategy in accordance with at least some embodiments of the present disclosure. In certain aspects, FIG. 13 depicts the Finite State Machine (FSM) node graph (left) and the resulting maneuver plan trajectory in the RIC frame (right). The FSM may allow users to string together a set of strategies and criterion to create autonomous unit behavior. Strategies may include Propagation, Relative Waypoint, Force Motion Circumnavigation (FMC), Natural Motion Circumnavigation (NMC), Linear Drift, Loop De Loop, Perch, Teardrop Waypoint, Tear Drop In Place, and Follow Sun. Each strategy may require a condition (e.g., criterion) to break from one node to the next. Criterion in the FSM may include On Complete, Epoch, and Range. Multiple criterion may be connected to the output of a strategy and criterion can connect to previous strategies to create looping behavior. The node graph allows these strategies and criterion to be connected in a visual way. The nodes provide a menu and input fields for users to tune strategy metrics. When the FSM is updated, the system may visualize the maneuver plan as trajectory in the viewport. The viewport is able to render the trajectory in the ECI, LLA, and RIC frames. In this illustrative embodiment, FIG. 13 shows a RIC centered Target satellite with a Unit satellite planning a FMC in the FSM. These features are associated with Modeling & Simulation API 110, Maneuver Planning 173, and RIC Frame Maneuvering.

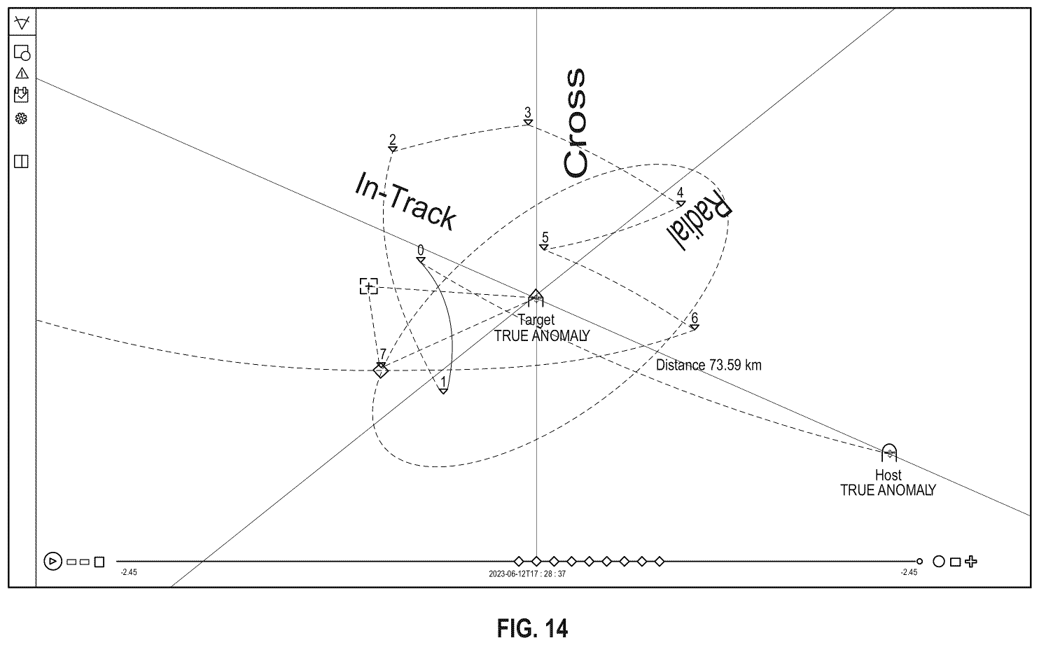

FIG. 14 shows a view of an illustrative relative frame view in accordance with at least some embodiments of the present disclosure. In certain aspects, FIG. 14 depicts the relative waypoint planner and users can select a target (chief) and a chaser (deputy) and quickly plan relative waypoint maneuvers. A 3D cursor/widget may be used to specify a waypoint in the relative frame on the target. After a new waypoint is placed, the system can update the relative trajectory between all the waypoints (maneuvers). Users can place as many waypoints as they want. These features are associated with Modeling & Simulation API 110, Maneuver Planning 173, and RIC Frame Maneuvering

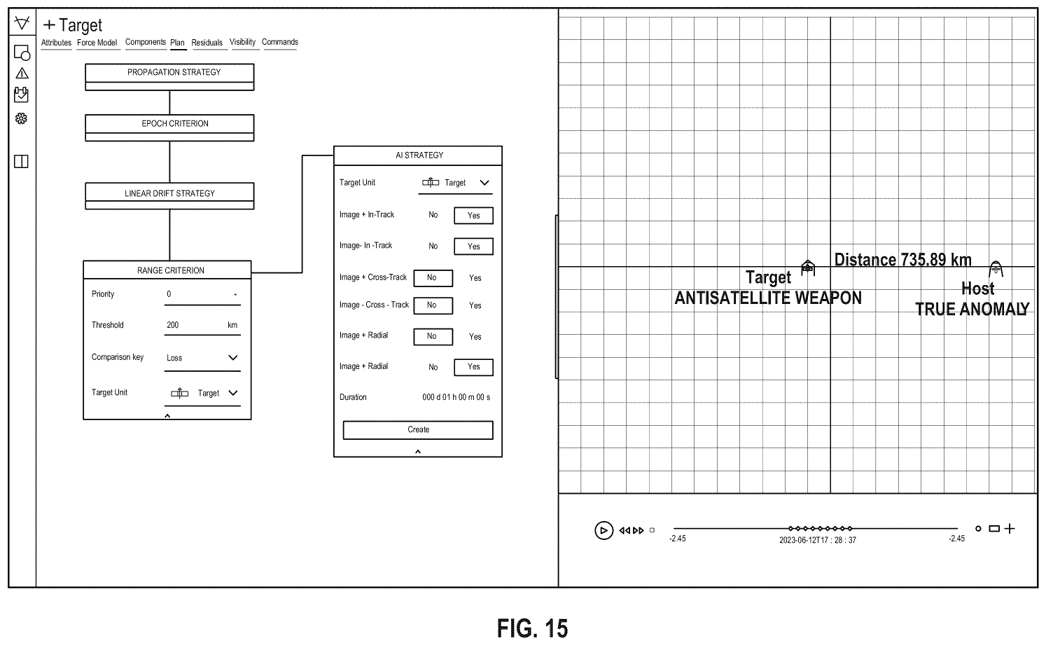

FIG. 15 shows a view of an illustrative development of a maneuver strategy in accordance with at least some embodiments of the present disclosure. In certain aspects, FIG. 15 shows the ability to set a number of criteria (e.g., distance, delta V used, time) each of which may be tied to a maneuver. In some aspects, it's a planner for an operator to say do maneuver A until X time passes, then do maneuver B until criteria Y or Z happens, then do C or D. This may tie directly to M&S API 110 and to Flight Dynamics 171. The operator can plan out the set of maneuvers in a simulation, and then execute the maneuvers against the actual satellite. The commands may be delivered via ground C2 159 and encode/decode 182, and via antenna broker 186 (e.g., for actual satellites). An advantage of doing one of these pre-defined maneuvers means that an operator doesn't have to execute a series of primitive commands, which can be composed into a single maneuver like an FMC or NMC (natural motion circumnavigation).

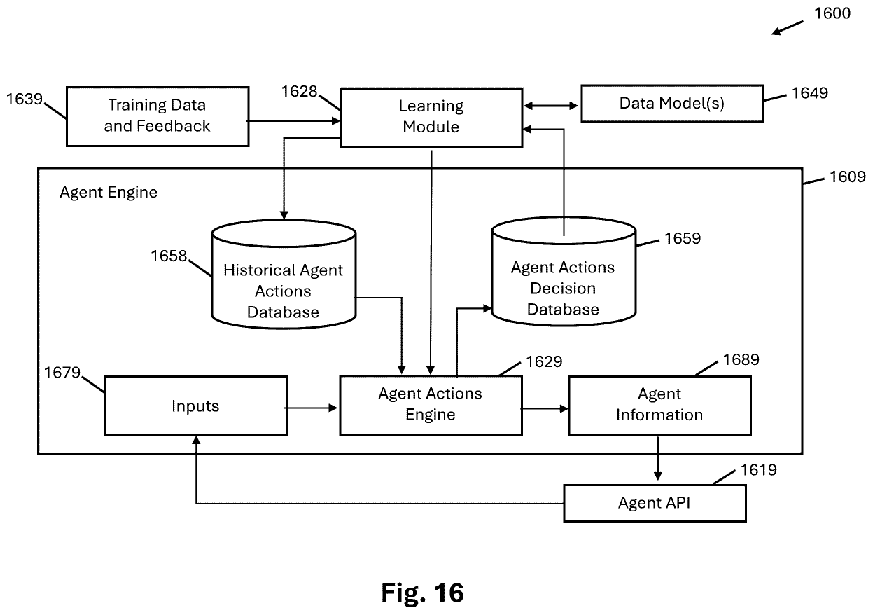

FIG. 16 shows an illustrative block diagram of an agent engine in accordance with at least some embodiments of the present disclosure. In some aspects, the components shown in FIG. 16 may correspond to like components shown in other figures. In FIG. 16, an agent engine 1609 interacts with agent API 1619 and a learning module 1628. The learning module 1628 receives input from training data and feedback 1639 and sends and receives information from data model(s) 1649. The agent engine 1615 includes a historical agent actions database 1658, an agent actions decision database 1659, an inputs 1679, an agent actions engine 1629, and agent information 1689.

The learning module 1628 may utilize machine learning and have access to training data and feedback 1639 to initially train behaviors of the learning module 1628. Training data and feedback 1639 contains training data and feedback data that can be used for initial training of the learning module 1628. The learning module 1628 may also be configured to learn from other data, such as scenario results, feedback, etc., which may be provided in an automated fashion (e.g., via a recursive learning neural network) and/or provided by a human. The learning module 1628 may additionally have access to one or more data model(s) 1649. The data model(s) 1649 may be built and updated by the learning module 1628 based on the training data and feedback 1639. The data model(s) 1649 may be provided in any number of formats or forms. Non-limiting examples of data model(s) 1649 include Decision Trees, Support Vector Machines (SVMs), Nearest Neighbor, and/or Bayesian classifiers.

The learning module 1628 may also be configured to access information from an agent actions decision database 1659 for purposes of building a historical agent actions database 1658. The agent actions decision database 1659 stores data related to agent decisions, including but not limited to historical agent actions, agent processing, agent notes, and other information related to agent actions. Agent actions information within the historical agent actions database 1658 may constantly be updated, revised, edited, or deleted by the learning module 1628 as the agent engine 1609 processes additional agent actions.

In some embodiments, the agent engine 1609 may include an agent actions engine 1629 that has access to the historical agent actions database 1658 and selects appropriate agent processing decisions (e.g., presented in agent information 1689) based on input from the historical agent actions database 1658 and based on inputs 1679 (inputs 1679 may include information about scenarios, agents, events, and actions, real-time information, historical information, and may include information that is internal or external to system 100). Non-limiting specific examples of information in inputs 1679 includes information about any agent action(s) recently executed for various agents and variations in actions by agents. The agent actions engine 1629 may make decisions regarding what information from inputs 1679 to provide to update agent actions based on any of the criteria described herein, including but not limited to information provided by the learning module 1628, information about current status of agent actions, feedback about agent actions (e.g., from agents, supervisors, agent training information, etc.), performance metrics related to agent actions or any of other aspects of agent actions. To enhance capabilities of the agent actions engine 1629, the agent actions engine 1629 may constantly be provided with information from training data and feedback 1639. Therefore, it may be possible to train an agent actions engine 1629 to have a particular output or multiple outputs. In various embodiments, the output of an AI application (e.g., learning module 1628) is an update AI agent action (e.g., a decision) that is sent, with appropriate information conveying how to apply the updated AI agent action(s) within system 100, via the agent actions engine 1629 and from agent information 1689, to the agent API 1619.

Using the inputs 1679 and the historical agent actions database 1658, the agent engine 1609 may be configured to provide agent information 1689 (e.g., one or more AI agent actions) to the agent API 1619 so that the agent API 1619 can publish one or more events, based on the agent information 1689. In various embodiments, the events may be published via the M&S API 110 to the scenario manager 101 to update one or more AI agent actions. An event of an updated AI agent action may be provided as an output of the agent actions engine 1629 (e.g., processed through the agent API 1619). For example, the AI agent(s) may advantageously function as a tactical decision aid for operators, where the AI agents autonomously map out waypoint plans that the operator then only needs to verify. The API may be a readily visible API that is exposed to an external system (e.g., a system external to the system 100 such as the agent engine 1609) and the API injects an event (e.g., an AI agent action event) into the system to modify an AI agent action on an ad-hoc basis based on the determinations (e.g., the agent information 1689) of the external system. AI agent actions become event-based data items, which can be determined in real-time and exposed to authorized applications to influence. In some aspects, there can be little or no manual configuration of agent actions and no static value for agent actions because the system 100 may use only AI agents and the AI agent actions may be set on an ad hoc basis. In some aspects, an AI or machine learning application may be enabled to integrate with the systems and methods disclosed herein in order to advantageously determine and implement updated and customizable AI agent actions. Such embodiments are advantageous by automating and quickly adjusting (with little or no manual configuration) agent actions so that outcomes are improved and resources are saved. Illustrative and non-limiting examples of advantages of using AI agents as disclosed herein, include an improved ability to assist maneuver planning, AI agents may be easily trained as they play many (e.g., thousands or millions) of individual RPO engagements, AI agents may be advantageously trained in a set of OpenAI Gym compliant environments, and the AI agents may be built to be lightweight and modular with advantageous speed and improved ease of debugging.

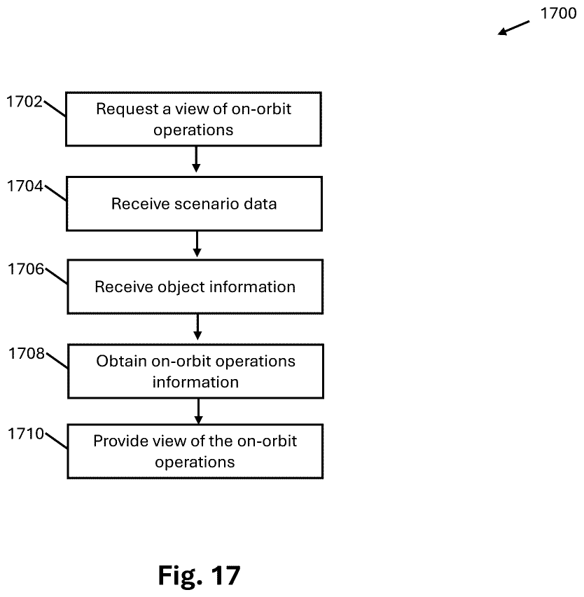

FIG. 17 is an illustrative method 1700 in accordance with at least some embodiments of the present disclosure. In FIG. 17, at step 1702, a request is made for a view of on-orbit operations. The request may be made using a pilot vehicle interface and the view may contain at least one object. At step 1704, scenario data is received from a simulation engine that is executing on a virtual machine. The scenario data describes a status of the on-orbit operations.

At step 1706, object information is received. The object information may be about how the at least one object interacts with the on-orbit operations. The on-orbit operations may be obtained in step 1708, where the on-orbit operations are an integration of the scenario data with the object information. At step 1710, the view of the on-orbit operations is provided. The view may be provided via the pilot vehicle interface.

The present disclosure, in various aspects, embodiments, and/or configurations, includes components, methods, processes, systems, and/or apparatus substantially as depicted and described herein, including various aspects, embodiments, configurations embodiments, sub-combinations, and/or subsets thereof. Those of skill in the art will understand how to make and use the disclosed aspects, embodiments, and/or configurations after understanding the present disclosure. The present disclosure, in various aspects, embodiments, and/or configurations, includes providing devices and processes in the absence of items not depicted and/or described herein or in various aspects, embodiments, and/or configurations hereof, including in the absence of such items as may have been used in previous devices or processes, e.g., for improving performance, achieving ease and/or reducing cost of implementation.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as any claims reflect, inventive aspects lie in less than all features of a single foregoing disclosed aspect, embodiment, and/or configuration. Thus, any claims are hereby incorporated into this Detailed Description, with each claim standing on its own as a separate preferred embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

### APPENDIX A

Systems and methods provided in the present disclosure effective performance of RPO mission planning, analysis, and trade studies.

In various embodiments, libraries are provided for performing RPO mission planning and analysis; Implementation of algorithms from textbooks, journal and conference papers, and technical documents are used; all code is written in C++ for speed, with APIs exposed to C and Python where necessary.
Illustrative Contents:
Numerical Algorithms Library—General numerical algorithms, similar to what would be found in Python's scipy library
Astrodynamics Library—General astrodynamics library for handling time, high-fidelity propagation, computing maneuvers, etc.
Discrete Event Simulation (DES)—Custom implementation of a discrete event simulation
Attitude Dynamics Library—Contains logic for propagating the attitude of a satellite forward in time
Filtering Library—General filtering library, built to generate measurements from instruments, and process them in filters
RPO Mission Planning Library—Library built to allow RPO missions to be scheduled on the DES through Finite State Machines (FSM), allowing for complex missions to be build. Also defines metrics for triggering events and logging information
State Estimation Library—Library built to allow state estimation and relative navigation to be performed within the DES

This appendix describes, for example, embodiments of the modeling and simulation (M&S) environment, including illustrative algorithms and capabilities.

In various embodiments:
Astrodynamics algorithms are heavily dependent on robust and efficient numerical algorithms
Modeling high fidelity propagation requires numerical integration or ordinary differential equations (ODEs)
Computing visibility intervals and range metrics require efficient root solvers
Optimizing maneuver plans requires flexible and efficient optimization algorithms
The numerical algorithms (numalg) library is designed to meet these needs, as required
Algorithms are only implemented when they support the astrodynamics related libraries

### Numerical Algorithms Library Overview

numalg—Math Library
Contains general functions to support other libraries
This library contains standard functions, which did not warrant further documentation numalg—Non-Linear Systems Library
Functions to solve non-linear systems of equations
Used to perform differential correction, allowing lambert solvers to account for high-fidelity perturbations
Algorithms:
Newton's Method: Algorithm 10.1 of Burden and Fairs [1]
Broyden's Method: Algorithm 10.2 of Burden and Fairs [1] numalg—ODE Library
Ordinary differential equation (ODE) solvers are essential to writing high-fidelity propagators, capable of accounting for perturbations
Multiple schemes have currently been implemented
Dormand-Prince (Dopri) schemes: Reasonably fast and reasonably accurate. Can handle both conservative and non-conservative accelerations
Runge-Kutta-Nystrom (RKN) schemes: Extremely fast and accurate, but can only handle conservative accelerations (can't handle drag or SRP)
Gauss-Jackson schemes: Slower, but highly accurate. Can handle both conservative and non-conservative accelerations
References for implemented schemes:
RKN 12 (10)—17:17 step, 12th order integrator with 10th order error control [2]
RKN 8(6)—9:9 step, 8th order integrator with 6th order error control [3, 4]
Dopri 8(7)—13:13 step, 8th order integrator with 7th order error control [5]
Dopri 5(4)-7:7 step, 5th order integrator with 4th order error control [6]
   numalg—Optimization Library
The optimization library supports the backend physics libraries, as
Currently have two algorithms implemented:
Genetic Algorithm-Single objective genetic algorithm used to optimize non-linear, multi-modal problems
Golden Section Method—Efficiently iterate to compute the minimum of a function along the specified search direction [7]
   numalg—Root Solver Library
Root solvers are key to efficiently computing when criteria are met within the astrodynamics libraries (i.e., computing when an object first comes into view)
Current algorithms implemented:
Bisection: Algorithm 2.1 of Burden and Fairs [1]
Fixed Point Iteration: Algorithm 2.2 of Burden and Fairs [1]
Newton-Raphson: Algorithm 2.3 of Burden and Fairs [1]

### Numerical Algorithms References

1. Burden, Richard L., Fairs, Douglas J. Numerical Analysis. Cengage Learning Asia Pte

Ltd, 2011.
2. J. R. DORMAND, M. E. A. EL-MIKKAWY, AND P. J. PRINCE “High-Order Embedded Runge-Kutta-Nystrom Formulae”, IMA Journal of Numerical Analysis 7(1987), 423-430
3. S. N. Papakostas and Ch. Tsitouras, “High phase-lag order Runge-Kutta and Nystrom pairs”, SIAM J. Sci. Comput. 21(1999) 747-763.
4. Ch. Tsitouras and S. N. Papakostas, “Cheap Error Estimation for Runge-Kutta methods”, SIAM J. Sci. Comput. 20(1999) 2067-2088.
5. J.R. Dormand and P.J. Prince, “High order embedded Runge-Kutta formulae”, Journal of Computational and Applied Mathematics. Vol. 7, Issue 1, (March 1981) 67-75.
6. Hairer, E., Norsett, S. P., and Wanner, G., Solving Ordinary Differential Eqautions 1:Nonstiff Problems. Springer-Verlag, 2008.
7. Katarzyna Zarnowiec (2022). golden section method algorithm (https://www.mathworks.com/matlabcentral/fileexchange/25919-golden-section-method-algorithm), MATLAB Central File Exchange. Retrieved Aug. 10, 2022.

Astrodynamics Tool-Kit (astrotk) Library

Astrotk Library Overview
The astrodynamics tool-kit (astrotk) is True Anomaly's base physics library
It is designed to be
Computationally efficient—written in modern C++
Scalable—No global variables, allowing it to be thread safe and parallelizable
Tunable—Supported fidelity ranging from linear dynamics (state transition matrices) to two-body dynamics, up to high fidelity force models
This is a general astrodynamics library, not focused on rendezvous and proximity operations (RPO)
The arda library at True Anomaly is focused on leveraging astrotk for performing RPO mission planning
Astrotk is being written to rival STK in fidelity, capability, and speed

Astronomy Library

Astrodynamics Tool-Kit (astrotk)
The astronomy library is focused on modeling important astronomy related phenomena
This is key for being able to account for high-fidelity perturbations, required for performing accurate, high-fidelity propagation of satellites

Astronomy Library—IERS EOP Data
The International Earth Rotation and Reference Systems Service (IERS) is the standard for providing detailed Earth orientation parameters (EOP)
Required to accurately model Earth's polar motion, precession, and nutation
IERS provides EOP data online at [1], to include the following for each day:
Earth's polar coordinates
UTC to UT1 time deltas
Length of day (LOD) adjustments
Nutation corrections
Celestial Intermediate Pole (CIP) offsets
In addition, text formats for all EOP data can be copied from:
Data for IAU 1980 standard: https://datacenter.iers.org/data/latestVersion/8_FINALS.DATA_IAU1980_V2013_018.txt
Data for IAU 2000 standard: https://datacenter.iers.org/data/latestVersion/10_FINALS.DATA IAU2000_V2013_0110.txt

### Astronomy Library—Sun Position

Astrotk supports low and high-fidelity calculations of the Moon's position
Low-Fidelity model: Algorithm 29 of Vallado's book [3,4]
Fast computations, accurate to 0.01° in angular position relative to Earth
High-Fidelity model: Jet Propulsion Laboratory's ephemerides [2]
Most accurate source for planetary ephemerides
Computationally expensive, and slightly slower than low-fidelity models

### Astronomy Library—Moon Position

Astrotk supports low and high-fidelity calculations of the Moon's position
Low-Fidelity model: Algorithm 31 of Vallado's book [3,4]
Fast computations, accurate to within 0.3° in ecliptic longitude, 0.2° in ecliptic latitude, and 1275 km in distance
High-Fidelity model: Jet Propulsion Laboratory's ephemerides [2]
Most accurate source for planetary ephemerides
Computationally expensive, and slightly slower than low-fidelity models

### Astronomy Library—Utility Functions

The utility functions module generally supports the accurate computation of nutation and precession
Functions compute metrics related to Earth orientation
Functions:
get_gmst()—Return the Greenwich Mean Sidereal Time (GMST) at a specified epoch [4,5]
get_gast()—Return Greenwich Apparent Sidereal Time (GAST) at a specified epoch [4,5]
get_earth_rotation_angle()—Return the Earth rotation angle (ERA) at a specified epoch [5], required for IAU 2000/2010 resolutions
get_mean_obliquity_of_ecliptic()—Return the mean obliquity of the ecliptic at a specified time [4,5]
eq_of_equinoxes()—Compute the equation of the equinoxes value at a specified epoch [4,5]
get_earth_rotation_rate_lod()—Return the Earth's rotation rate accounting for variations in the length of day (LOD). LOD values are provided by IERS technical bulletins [5]

### Burn Modeling Library

Astrodynamics Tool-Kit (astrotk)
The burn modeling library contains the classes required to represent impulsive and finite burns
These classes are leveraged to apply impulses or finite burns on satellite objects
Enable low level parameters to be defined to support finite burns, abstracting away the complexities of physical objects such as thrusters to the values required to numerically integrate finite burns
These classes will be expanded, as necessary to properly model maneuvers at the required level of fidelity

### Geopotential Library

Astrodynamics Tool-Kit (astrotk)
The geopotential library provides classes to store and access gravitational coefficients from the various geopotential
Used to model Earth's aspherical mass distribution
Gravity models implemented (we will use the most accurate version available, but will support older versions for backwards compatibility)
JGM-3—Joint gravity model 3 [6, 10]
EGM-96—NASA GSFC and NIMA joint geopotential model for 2006 [6, 11]
EGM-2008—NASA GSFC and NIMA joint geopotential model for 2008 [12, 13]

### Lambert Library

Astrodynamics Tool-Kit (astrotk)
Efficiently solving lambert's problem is essential to maneuver planning in an astrodynamics library
It is key to support:
Multi-revolution solutions
High-fidelity lambert solvers leveraging differential correction
Algorithms implemented:
Lambert Universal: single revolution universal variables lambert solver [5]
Arora's lambert solver: multi-revolution lambert solver[14]
Differential correction used to account for perturbations [5, 15]
Battin, Gooding, and Blair Thompson's algorithms will be implemented later [16, 17, 18]

### Maneuver Solver Library

Astrodynamics Tool-Kit (astrotk)
The maneuver solver functions compute the impulses or finite burns required to maneuver a satellite to achieve a desired goal
Target a waypoint, change orbit, etc.
Impulsive and finite versions of the maneuver solvers are required
Method used by analyst depends on required level of fidelity
Maneuver solver types:
General Solvers: Fixed transfer time, trading against multi-revolution lambert options to minimize delta V
Arrival time solvers: Trade off coast vs. transfer time to reach desired waypoint at specific time while minimizing delta V
Arrival window solvers: Trade off coast vs. transfer time to reach the desired waypoint within the specified time window while minimizing delta V

### Orbit Library

Astrodynamics Tool-Kit (astrotk)
The orbit library contains routines for computing orbit related
The orbit library is a general support library for other higher-level operations

### Orbit Library—Anomaly Conversions

Anomaly conversions are necessary when converting between position/velocity vectors, and classical orbital element (COE) sets
Algorithms for anomaly conversions are all pulled from Vallado [5]
Algorithms implemented:
True anomaly to Eccentric/Parabolic/Hyperbolic anomaly (Vallado Algorithm 5)
Eccentric/Parabolic/Hyperbolic anomaly to true anomaly (Vallado Algorithm 6)
True anomaly to Mean anomaly (Vallado, Algorithms 2, 5)
Mean anomaly to true anomaly (Vallado, Algorithms 2, 6)

### Orbit Library—Coordinate

### Transformations

Coordinate transformations to relative reference frames are key enablers for rendezvous and proximity operations (RPO) mission planning
Relative frames are defined w.r.t. a reference of “chief” satellite
Current coordinate transformations implemented to rotate from Earth-Centered-Inertial to the following [5]:
Radial, in-track, cross-track (RIC):
r [symbol] is along the radial direction from earth through the reference satellites position, c [symbol] is in the direction of angular momentum, i [symbol] is completed by the right-hand rule, and is along the direction of the velocity vector
Local-Vertical, Local-Horizontal (LVLH):
r [symbol] is along the radial direction from the reference satellite's position to Earth, c [symbol] is in the OPPOSITE direction of angular momentum, i [symbol] is completed by the right-hand rule, and is along the direction of the velocity vector
Velocity, Normal, Bi-Normal (VNB):
v [symbol] is along the reference satellite's velocity vector, n [symbol] is in the direction of angular momentum, b is completed by the right-hand rule

### Orbit Library—Mean-Osculating

### Conversions

The conversion between mean and osculating elements is important for several areas in astrodynamics:
Numerical integration is performed on osculating elements [5]
Two-Line Element (TLE) sets are defined using mean elements [5]
Formation design is generally done using mean elements
Brouwer-Lyddane theory is implemented to perform the conversion between mean and osculating elements [19, 20]
Used for instantaneous conversion between mean and osculating elements
As only the instantaneous conversion is performed, secular terms are ignored
Mean elements are averaged using only the J2 perturbation in this case

### Orbit Library—State Transformations

State transformations convert between various state representations from within the same coordinate system
We aren't changing the coordinate system, just how we represent that state in the current coordinate system
Transformations currently implemented:
Convert between ECI position/velocity and classical orbital elements (COE) [5]
Convert between COE and equinoctial orbital elements (EOE) [5]
Convert from ECI position/velocity to latitude, longitude, and altitude (LLA) [5]
Convert from ECEF position/velocity to LLA [5]

### Propagation Library

Astrodynamics Tool-Kit (astrotk)
The astrotk propagation library supports a range of propagation methods
Low-fidelity: Keplerian two-body dynamics
High-fidelity: Numerically integration with the option to include high-fidelity perturbation models and finite burns or thrust accelerations

### Propagation Library

Algorithms implemented:
kepler_coe()—Keplerian, two-body dynamics [5]
Incredibly fast but not applicable for high-fidelity simulations
numerical_integration()—High-fidelity, numerical integration accounting for high-fidelity perturbations [4, 5]
Leverages ODE solvers from the numerical algorithms library
High fidelity force model supports . . .
Up to 100×100 gravity field
Perturbations due to sun/moon third bodies
Drag and solar radiation pressure (SRP) perturbations will be modeled soon
steered_burn()—Numerically integrated finite burns
On top of the perturbation included within the numerical_integration() function, support the application of finite thrusts
Thrusts are assumed to be fixed in a specified reference frame
Thrust vectoring is not yet supported

### Reduction Theories Library

Astrodynamics Tool-Kit (astrotk)
Reduction theories are used to convert between body-fixed and inertial frames
IAU-76/FK5 reduction: Standard up until IAU-2000 reduction theory was introduced [5]
Inertial Frame: J2000 mean-equator, mean equinox of date
Corrections exist for the nutation and obliquity values to make the transformation compatible with later IAU reductions definitions of the GCRF frame [5]
Body-fixed frame: International Terrestrial Reference Frame (ITRF) or Earth-Centered, Earth-Fixed (ECEF)
IERS 2003 Conventions: Became new standard when IERS Tech. Note 32 was released [5, 8]
Inertial frame: Geocentric Celestial Reference Frame (GCRF)
Body-fixed frame: International Terrestrial Reference Frame (ITRF)
IERS 2010 Conventions: Became new standard when IERS Tech. Note 36 was released [5, 9]
Same frames as IAU-2000 reduction, with updated and more accurate measurements/corrections

### State Representations Library

Astrodynamics Tool-Kit (astrotk)
The state representations library defines the various ways in which an astrodynamics state can be defined
These are represented as classes in the astrotk library
Conversion between the various state representations are supported

### State Representations Library

State class:
Defines a position/velocity in an ECI frame [4, 5]
Can represent either the J2000 frame from the FK5 reduction theory, or the GCRF frame from the IAU-2000/2010 reduction theories
Classical orbital elements (COE) [4, 5]
Supports mean vs. osculating elements ([19, 20]), and mean/true anomaly [4, 5]
Equinoctial orbital elements (EOE) [4, 5]:
Non-singular version of COEs
Supports mean vs. osculating elements ([19, 20])
Two-line element (TLE or elsets) sets [5]
Elsets are available to the general public through the Air Force Space Command (AFSPC)
Commonly used in military applications, though contains considerable errors in position, partially due to formatting limitations

### Time Library

Astrodynamics Tool-Kit (astrotk)
Astrotk supports multiple representations or systems of time, along with the corresponding transformations between the various time systems [4, 5]
UTC: Universal Coordinated Time
UT1: Observed Solar Time
TAI: International Atomic Time
TT: Terrestrial Time
TDB: Barycentric Dynamical Time
There are several ways in which time can defined in astrotk:
DeltaEpoch (class)-Used to define a duration of time
GregorianDate (class)-Used to define an absolute time as a Gregorian date (year, month, day, hour, minute, second)
Time system must be specified, but is not fixed
Epoch (class)-Used to define an absolute time as a Gregorian date in the UTC time system
This is the base unit of time within astrotk
Julian Date—fractional number of days from an origin time [5]
JD—Fractional number of days from Jan. 1, 4713 B.C., 12:00
MJD—Fractional number of days from Nov. 17, 1858 at 00:00:00
MJDJ2k—Fractional number of days from Jan. 1, 2000 at 12:00:00
Conversions between the various Julian Date definitions, and between Julian Date and Gregorian Date definitions are provided by the time library [5]

### Waypoints Library

Astrodynamics Tool-Kit (astrotk)
Waypiont classes provide maneuvers with a waypoint to target, either in inertial space or in relative space
Inertial Waypoints: Define a waypoint to target in inertial space
ECIWaypoint: Specify waypoint in an Earth-Centered-Inertial frame
ClassicalWaypoint: Specify a waypoint using classical orbital element sets
Relative Waypoints: Define a waypoint relative to a reference satellite
RICWaypoint: Waypoint is specified in the radial, in-track, cross-track frame
LVLHWaypoint: Waypoint is specified in the local-vertical, local-horizontal frame

### Astrotk References

1. “Earth orientation data.” IERS, 10 Aug. 2022, https://www.iers.org/IERS/EN/DataProducts/EarthOrientationData/eop.html.
2. “The SPICE Toolkit.” JPL, 10 Aug. 2022, https://naif.jpl.nasa.gov/naif/toolkit.html.
3. Meeus, J., Astronomical Algorithms, Willman-Bell, Richmond, VA, 1991.
4. Montenbruck, O., and Gill, E., Satellite Orbits: Models, Methods, and Applications, Springer, New York, 2001.
5. Vallado, D. A., Fundamentals of Astrodynamics and Applications 3rd Ed., Kluwer Academic, Boston, MA, 2001.
6. “General Mission Analysis Tool (GMAT)”, NASA, 10 Aug. 2022, https://software.nasa.gov/software/GSC-17177-1.
7. Claude Boucher, Zuheir Altamimi, Patrick Sillard, and Martine Feissel-Vernier: The ITRF2000. (IERS Technical Note; 31) Frankfurt am
Main: Verlag des Bundesamts für Kartographie und Geodäsie, 2004. 289 pp., paperback, ISBN 3-89888-881-9 (print version)
8. IERS Conventions (2003). Dennis D. McCarthy and Gérard Petit. (IERS Technical Note; 32) Frankfurt am Main: Verlag des
Bundesamts für Kartographie und Geodäsie, 2004. 127 pp., paperback, ISBN 3-89888-884-3 (print version)
9. IERS Conventions (2010). Gérard Petit and Brian Luzum (eds.). (IERS Technical Note; 36) Frankfurt am Main: Verlag des
   Bundesamts für Kartographie und Geodäsie, 2010. 179 pp., ISBN 3-89888-989-6
10. B.D. Tapley, et. al, “The Joint Gravity Model 3”, Journal of Geophysical Research (1996).
11. “Earth Gravitational Model 96 (EGM96)” National Geospatial-Intelligence Agency, 11 Aug. 2022, https://earth-info.nga.mil/index.php?dir=wgs84&action=wgs84 #tab_egm96
12. The development and evaluation of the Earth Gravitational Model 2008 (EGM2008)-Nikolaos K. Pavlis, Simon A. Holmes, Steve C. Kenyon, John K. Factor; Journal of Geophysical Research: Solid Earth (1978-2012) Volume 117, Issue B4, April 2012.
13. “Earth Gravitational Model 2008 (EGM2008)” National Geospatial-Intelligence Agency, 11Aug. 2022, https://earth-info.nga.mil/index.php?dir=wgs84&action=wgs84 #tab_egm2008
14. Arora, N., Russell, R. P., A fast and robust multiple revolution lambert algorithm using cosine transformation, AAS, 13-728.
15. DiPrinzio, Marc. Methods of Orbital Maneuvering, American Institute of Aeronautics and Astronautics, Reston, VA, 2019.
16. R. H. Battin, An Introduction to the Mathematics and Methods of Astrodynamics. New York: American Institute of Aeronautics and Astronautics, 1987.
17. B. F. Thompson, D. Brown, R. Cobb, Complete solution to the lambert problem with perturbations and target state sensitivity, AAS, 18-074
18. R. H. Gooding, A procedure for the solution of lambert's orbital boundary-value problem, Celestial Mechanics, Vol. 48, 1990, pp. 145-165
19. Brouwer, Dirk. 1959. Solutions of the Problem of Artificial Satellite Theory Without Drag.

### Astronomical Journal. 64 (1274): 378-397

20. Lyddane, Robert H. 1963. Small Eccentricities or Inclinations in the Brouwer Theory of the Artificial Satellite. Astronomical Journal. 68 (8): 555-558.

### Sim Library

### Discrete Event Simulation

The sim library is the underpinning framework of True Anomaly's persistent simulation
It is designed to be
Computationally efficient—Written in modern C++ using efficient design patterns
Scalable—Fundamental modularity supports various parallelization schemes
Tunable—Event based framework easily converted to fixed timestep execution when needed
This is a general simulation library, not focused on rendezvous and proximity operations (RPO)
The arda and casper libraries at True Anomaly are focused on leveraging sim for modeling complex RPO missions
Sim is being written to support headless trade studies as well as a web based distributed front-end

### Observer Pattern

### Sim

A classic design pattern from the Gang of Four
Modified to work with the event-based timeline of our simulation
Observable objects queue notifications when their state changes
When notifications are dispatched by the timeline, attached Observers receive the updated state
Prevents unnecessary polling

### Timeline

### Sim

Service provider simulation facilitates specialized Timeline implementations depending on application
Event based timeline enables dynamic step sizes
No events are missed, meaning simulation never needs to rewind
Can emulate discrete time simulation through use of TimestepEvents
Breakpoints and ConditionalBreakpoints allow arbitrary pausing of the Simulation
ConditionalEvents enable event execution contingent on criteria
Schedulers add events to the timeline when criteria are satisfied

### Criterion

### Sim

Criterion observe other objects in the simulation to monitor for various conditions
SimpleCriterion compare current values against a provided threshold
BooleanCriterion allow for boolean combinations of various other criteria
ComplexCriterion allow for user defined combinations of various other criteria

### Metrics

### Sim

Metrics provide common functionality for any measurable quantity of interest in the simulation
ICriteriaMetrics can be used as MetricCriteria for triggering events/decisions
ILoggableMetrics can be logged to file at either a fixed cadence (MetricLogEvent) or on each notification (MetricLogObservable)

### State Machine

### Sim

State machines are a common design pattern for defining behaviors
FiniteStateMachine provides common functionality for state machines in the simulation
IFiniteStateMachineNode defines the interface for the nodes of an FSM
CriteriaNode implements this interface to allow criteria to function as the edges in the graph

### Arda Library

### Rendezvous and Proximity Operations Mission Planning Library

The arda library is True Anomaly's rendezvous and proximity operations (RPO) mission planning library
It is designed to be
Computationally efficient-written in highly object-oriented modern C++
Scalable—focus on maximizing flexibility while minimizing global awareness to allow simultaneous modeling of RPO missions across the constellation
Tunable—Supports full range of fidelity available via astrotk, as well as tuable levels of attitude dynamics fidelity
This library models RPO missions using true state knowledge
Designed to seamlessly integrate with casper to facilitate RPO mission modeling with realistic state estimation
Arda is being written to provide unparalleled RPO mission planning
Rendezvous and Proximity Operations (RPO) Missions are modeled as Finite State Machines (FSM)
Nodes are individual “Strategies” which handle individual behaviors/phases
Edges are criteria defining the transition from one state to the next
Strategies of varying levels of complexity
Simple fixed time waypoint targeting
Parameterized description of complex behaviors (ie-inspection tasking, maintaining an engagement zone, etc)
The combination of decision tree style FSMs and parameterized strategies enables highly complex and nuanced missions to be defined with relative ease

### Burns

### Arda

Utilizes AstroTK for burn solving
Wraps these solutions as events
Scheduled on the Timeline
Can be replanned/cancelled depending on the Mission definition
Tracks thruster assignment and fuel usage

### Maneuvers

### Arda

Utilizes AstroTK for maneuver solving
Defines common functionality used by various strategies for waypoint targeting
The most basic strategies simply target waypoints using one of these

### Formation Builders

### Arda

Used for Satellite initialization and for parameterized Strategies
Wheel Formations
J2Invariant, Standard, and Quadrant Time-Centered [1] [4] [5]
Perch Formations
Leader-Follower, Flat-Circular, Rectilinear, and Boomerang [1] [4] [5]

### Attitude Modeling

### Arda

### Attitude Modeling

Command Attitude Propagator for low fidelity enforcement of attitude based constraints
Standard Attitude Propagator modeling torque application, spin rates, and attitude based constraints
Pointing Strategies
Prioritize fuel by pointing thrusters for optimal burn execution
Prioritize sensor tasking by pointing for optimal sensor views

### Satellite/Vehicle Modeling

### Arda

Components
Allow modular vehicle definition
Aggregate mass and moment of inertia for thrust/torque modeling
Cross sectional area for visibility and drag/SRP perturbations
Body frame pointing for attitude based constraints
Controllers
Seamlessly switch between true view of satellites and state estimation
Add and remove target views/filters dynamically
Contain logic to balance pointing strategies and maneuver strategies
Pointing Strategies
Prioritize fuel by pointing thrusters for optimal burn execution
Prioritize sensor tasking by pointing for optimal sensor views

### Metrics

### Arda

Utilizes metrics framework provided by sim library
All metrics can be logged to file on both a fixed cadence and as notified by their Observable
Certain metrics can be used as criteria for decision points in the simulation

### Waypoint Planners

### Arda

Dynamic Station Keeping-Maintain relative state constraint (subject to defined allowable bounds) using repeated burns
Forced Motion Circumnavigation—Target a series of waypoints tracing a piecewise circle about the reference/target
Follow Sun—Target a series of waypoints placing yourself along the vector from the target to the sun
Dock/Undock—Perform a multi-impulse glideslope docking or undocking procedure [2] [3]
Linear Drift-Plan a waypoint to execute a linear drift relative to the reference/target
Racetrack—Plan a repeated series of 4 waypoints with 2 periods of linear drift (1 super-, 1 sub-) forming a “racetrack” about the reference/target

### Arda References

[1] J. Kulik, “An in-Plane J2-Invariance Condition and Control Algorithm for Highly Elliptical Satellite Formations,” Celest Mech Dyn Astr, vol. 133, no. 2, p. 4, February 2021, doi: 10.1007/s10569-021-10003-1.
[2] S. Cuevas, H. Urrutxua, and P. Solano, “Dynamics, Guidance and Control for Autonomous Rendezvous and Docking in the Restricted Three Body Problem,” p. 12.
[3] H. B. Hablani, M. L. Tapper, and D. J. Dana-Bashian, “Guidance and Relative Navigation for Autonomous Rendezvous in a Circular Orbit,” Journal of Guidance, Control, and Dynamics, vol. 25, no. 3, pp. 553-562, May 2002, doi: 10.2514/2.4916.
[4] H. Schaub and K. T. Alfriend, “J2 Invariant Relative Orbits for Spacecraft Formations,” p. 19.
[5] S. D′Amico and O. Montenbruck, “Proximity Operations of Formation-Flying Spacecraft Using an Eccentricity/Inclination Vector Separation,” Journal of Guidance, Control, and Dynamics, vol. 29, no. 3, pp. 554-563, May 2006, doi: 10.2514/1.15114.

### Casper Library

### State Estimation and Filtering Library

CASPER is a library for providing the capability to run filters and instrument models in the simulation.
Sub Libraries:
Filters Library: Contains state estimation filters
Measurement Generators Library: Contains models of spacecraft instruments
Measurements Library: Defines data structures that contain measurements which are passed from the instrument models to the filters
This library can be used to evaluate filter performance with simulated instruments, and to evaluate mission performance based on the current configuration of filters and instrument models.
Designed to be modular so that new filters, instrument models, and measurements can be seamlessly integrated with each other and the rest of the simulation framework.

### Filter Library

### Measurements Library

### Measurement Generators Library

### CASPER Simulation Example

### Simulation Flow:

1. Instrument models get the truth state from the satellites they are observing.
2. Instrument models generate a noisy measurement based on the truth state and generate a measurement data structure which is then passed to the filter.
3. Filters ingest this measurement and generated a state estimate that can be used by a controller.
   Various embodiments of the present disclosure provide:
   Pilot—a mission control system (MCS) with tools and features to command and control live spacecraft
Battle Management-tactical command and control of many assets in the space domain
Space Domain Awareness (SDA)—a collection of features enabling data collection and fusion of SDA
Digital Range—detailed modeling and simulation services for space assets
Ascension—environment for space operations training and wargaming that includes:
Scalable, location-agnostic multiplayer
“Career” mode for training
Game-ified tactics development
AI-assisted Tactics development
AI-assisted training development

Mosaic is a common platform and interface for space mission operations, training, and simulation. It features a high-fidelity modeling and simulation backend tailored for Rendezvous and Proximity Operations (RPO), but extensible for general purpose astrodynamics simulation. Mosaic also features a graphical front-end for input and visualization, including inertial frames, relative frame orthographic projections, waypoint trajectory planning, and information displays. Application Programming Interfaces (API) are available for batch-scripting astrodynamics analysis. Mosaic is cloud-based, enabling easy access to “Simulation-as-a-Service”, a high-performance compute architecture supporting massively parallel Monte-Carlo-type analyses, and satellite operations from anywhere. This environment provides analyses and planning tools for both space defense and commercial Orbital Servicing, Assembly, and Manufacturing (OSAM) applications.

The Pilot Vehicle Interface (PVI) will include the following features:
1. Access to live system status and control of True Anomaly satellites
2. Modeling and simulation for future architecture studies
3. Gaming platform for multiplayer orbital warfare training
4. Assist maneuver planning with AI

The agents (AI) are developed using an in-house developed RL framework
Built to be lightweight, modular, fast, and easy to debug
Trains agents as they play thousands or millions of individual RPO engagements
Agents are trained in a set of OpenAI Gym compliant environments
These serve to wrap the simulator in such a way to expose task specific functionality
The agents get integrated into the simulator (PVI backend) These tasks include cooperative inspection, [v] OEM (dogfighting), orbital intercept (ingress)
by extracting the learning weights directly from the network and loading them into the C++ code.
This keeps overhead low as it requires no additional C++ packages to execute.
This allows the AI to function as a tactical decision aid for operators, where the agents autonomously mapping out waypoint plans that the operator then only needs to verify
Automation via Expert Systems is enabled using Finite State Machines (FSM)
States specify various semi-autonomous behaviors, where goals are defined parametrically and maneuvers are calculated on the fly
Transitions between States are controlled by user defined criteria using real time data
State machines allow canonical RPO primitive behaviors (e.g. Forced Motion Circumnavigation, linear drift) to be strung together into a complete mission plan
Pre-constructed state machines enable automated behaviors of both adversaries and allies for training purposes
   Various embodiments provide:
Universal and plug n play MCS API
MCS is composed of a number of services that have interchangeable parts that can be used with different vendor software or custom True Anomaly software components such as different flight software or custom command and telemetry databases for distinct spacecraft
Custom and extensible data providers can be added through a provider behavior
Agnostic to encryption schemes
Headless API for use with “Pilot” or other PVIs such as AstroUX-inspired frontends
Scalable MCS for RPO missions
The software supports hundreds of concurrent satellites each satellite's command and control isolated through specific channels providing fault tolerance and isolated failure
   Tactical decision aids, including:
Residuals
Visibility Windows/Access Times
Transfer/Intercept Porkchop Plot
Covariance
Point of Close Approach
Camera To Sun Angle
Range Rate
Reachability Analyses and Visualization
   Multiplayer capabilities, including:
1 v 1 or n v n teams from any ITAR-compliant location in the world
Scenario/game browser—Custom scenario creation and private/public hosting
Network synchronized time—Client clock is auto synced on scenario load
Team-based database—Each team is assigned read/write access to separate authoritative sources of truth. Only White Cell has override ability to the truth and team databases.
Team-based physics engine—Each team is assigned a different propagator to emulate team/country fidelity
Networked Objectives—Each team/player is assigned custom objectives. Progress/completion is tracked digitally.
Leaderboard—Dynamically assign success criteria to global and team-based objectives. Scenario performance reporting is automated.
Player versus Computer—Design Red Team behaviors at the constellation/unit level, driven by AI
Player Positions—Assign player roles per team
Replay—Return to a previous stat

1. A method for viewing on-orbit operations, the method comprising:
requesting, using a pilot vehicle interface, a view of the on-orbit operations, wherein the view comprises at least one object;
receiving, from a simulation engine executing on a virtual machine, scenario data describing a status of the on-orbit operations;
receiving object information about how the at least one object interacts with the on-orbit operations;
integrating the scenario data with the object information to obtain the on-orbit operations; and
providing, via the pilot vehicle interface, the view of the on-orbit operations.

2. The method of claim 1, wherein the at least one object comprises at least one of a ground station and at least one of a satellite.

3. The method of claim 1, wherein the scenario data comprises launch information, and wherein the object information comprises a calculation of orbital data that is based on the launch information.

4. The method of claim 1, wherein the at least one object is not on-orbit, and wherein the view of the on-orbit operations is a simulation of at least two scenarios of the at least one object being on-orbit.

5. The method of claim 4, wherein after the view of the simulation, the at least one object is on-orbit and a second view is provided that displays on-orbit information for the at least one object after it is on-orbit.

6. The method of claim 1, wherein the view of the on-orbit operations comprises a first simulation that models a first on-orbit maneuver of the at least one object, and further comprising:
providing a second view of the on-orbit operations that comprises a first simulation that models a first on-orbit maneuver of the at least one object;
requesting the view of the on-orbit operations a second time;
providing the view, wherein the view reverts back in time to remove the first simulation;
requesting a third view of the on-orbit operations that comprises a second simulation that models a second on-orbit maneuver of the at least one object; and
providing the third view of the on-orbit operations that comprises the second simulation that models the second on-orbit maneuver of the at least one object.

7. The method of claim 1, wherein the view of the on-orbit operations is a view of simulated operations, and further comprising:
requesting a second view of the on-orbit operations, wherein the second view comprises real-time operations of the at least one object; and
providing the second view of the real-time operations.

8. The method of claim 7, further comprising:
requesting an on-orbit maneuver of the at least one object; and
sending, via a scenario manager, a command to execute the on-orbit maneuver to the at least one object.

9. The method of claim 1, further comprising receiving, from an AI agent, an action to maneuver the at least one object.

10. The method of claim 9, wherein the action is provided as a simulation in the view by the pilot vehicle interface.

11. The method of claim 9, wherein the at least one object is on-orbit in real-life, and further comprising receiving a confirmation of the action and sending a command to execute the action in real-life to the at least one object.

12. The method of claim 11, wherein the command is executed faster than in real-time.

13. The method of claim 1, further comprising sending, by a scenario manager, a command to the at least one object that is on-orbit that causes the at least one object to execute a maneuver.

14. The method of claim 13, further comprising: receiving, by the scenario manager, telemetry data from the at least one object, wherein the telemetry data is based on the command.

15. A system for viewing on-orbit operations, the system comprising:
a simulation engine executing on a virtual machine, the simulation engine providing scenario data describing a status of the on-orbit operations; and
a pilot vehicle interface requesting a view of the on-orbit operations, receiving the scenario data from the simulation engine, receiving object information about how an at least one object interacts with the on-orbit operations, integrating the scenario data with the object information to obtain the on-orbit operations; and providing the view of the on-orbit operations.

16. The system of claim 15, wherein the simulation engine executes in at least five modes, the modes comprising: command and control, space battle management, battlespace, tactical decision aids, and digital space range.

17. The system of claim 16, wherein the at least one object is viewed as a launch vehicle analysis in each of the five modes.

18. The system of claim 16, wherein a state estimation library is used in the battlespace mode to provide a white cell.

19. The system of claim 15, wherein the pilot vehicle interface executes on the virtual machine.

20. The system of claim 19, wherein the system relies on a single clock.
